(19) United States
(12) Patent Application Publication
(10) Pub. No.: US 2025/0067972 A1
(43) Pub. Date: Feb. 27, 2025

(54) PIEZOELECTRIC MIRROR COMPONENT, METHOD FOR OPERATING THE PIEZOELECTRIC MIRROR COMPONENT, AND PROJECTION APPARATUS HAVING THE PIEZOELECTRIC MIRROR COMPONENT

(71) Applicant: TDK Electronics AG, München (DE)

(72) Inventors: Matthias WULF, Graz (AT); Franz RINNER, Frauental an der Lassnitz (AT)

(73) Assignee: TDK Electronics AG, München (DE)

(21) Appl. No.: 18/722,383

(22) PCT Filed: Dec. 7, 2022
(86) PCT No.: PCT/EP2022/084818

§ 371 Date: Jun. 20, 2024

(30) Foreign Application Priority Data
Dec. 22, 2021 (DE) 10 2021 134 310.0

(51) Int. Cl. G02B 26/08; G03B 21/00

(52) U.S. Cl. CPC G02B 26/0858; G03B 21/008

(57) ABSTRACT

A piezoelectric mirror component including a mirror element, a piezoelectric drive ring which surrounds the mirror element and is connected to the mirror element by way of at least one first torsion spring element, and a frame element connected to the drive ring via at least one second torsion spring element is specified, wherein the drive ring has a first diameter in a first direction and a second diameter in a second direction perpendicular to the first direction, and the first diameter is greater than the second diameter. A method for operating the piezoelectric mirror component and a projection apparatus are also specified.

### CROSS-REFERENCE TO RELATED APPLICATIONS

The present application is a national stage entry from International Application No. PCT/EP2022/084818, filed on Dec. 7, 2022, published as International Publication No. WO 2023/117433 A1 on Jun. 29, 2023, and claims priority to German Patent Application No. 10 2021 134 310.0, filed Dec. 22, 2021, the disclosures of all of which are incorporated by reference herein in their entireties.

### FIELD

A piezoelectric mirror component, a method for operating the piezoelectric mirror component and a projection device with the piezoelectric mirror component are disclosed.

### BACKGROUND

There is a wide region of applications for laser projectors. For example, projectors are used to display moving images, for example in cinemas, for home cinema applications or for mobile display applications. Projectors that are cost-effective and insensitive to oscillations should be particularly available for this purpose. Furthermore, projectors are increasingly being used in the automotive sector, for example for projecting information onto the road surface, for matrix illumination or for applications based on the LIDAR principle (LIDAR: “light detection and ranging”). Such applications require a great depth of field, which laser projectors can provide. Laser projectors are also advantageous for applications in conjunction with VR (“virtual reality”) and AR (“augmented reality”), for example in AR/VR glasses.

A projector can have rotatable mirrors by means of which a time-modulated laser beam is deflected. In this way, an image is generated in the far field perceived by a viewer, so that the projected image is always in focus for the viewer and no accommodation of the eye is necessary. In the case of AR/VR glasses, for example, the deflected beam is coupled into a waveguide lens. Here, the direction and not the position of the beam determines the position of the image point for the viewer, so that no further optics are required. Two mirrors are often used, one for each orthogonal deflection direction, by means of which a laser beam scans the image region in an orthogonal grid. Alternatively, there are also solutions with laser arrays, LED arrays (LED: light emitting diode) or QLED arrays (QLED: quantum dot light emitting diode), which are, however, limited in their resolution and brightness, as well as solutions in which laser light is selectively reflected by a passive panel, although this is not very energy-efficient. There is therefore a high demand for compact solutions for AR/VR glasses with good image resolution.

For example, micromirrors are known from the following publications: The publication U. Baran et al, “Resonant PZT MEMS Scanner for High-Resolution Displays”, Journal of Microelectromechanical Systems, 21, 1303-1310, 2012 describes a mirror that can oscillate around one axis and thus enables one-dimensional scanning. The publication Ch. Pan et al, “A New Two-Axis Optical Scanner Actuated by Piezoelectric Bimorphs”, International Journal of Optomechatronics, 6, 336-349, 2012 describes a two-dimensionally movable rectangular mirror, wherein the movement in one direction is an anharmonic movement in a so-called rocking mode. The publication JP 5345102 B2 and H.-J. Quenzer et al, “Piezoelectrically driven translatory optical MEMS actuator with 7 mm cut-outs and large displacements”, Proc. SPIE 9375, MOEMS and Miniaturized Systems XIV, 937500, 2015 describe symmetrically suspended mirrors that can be moved about two axes and whose movements about both axes are similar, which can lead to undesirable coupling behavior. The publication M. Tani et al, “A Combination of Fast Resonant Mode and Slow Static Deflection of SOI-PZT Actuators for MEMS Image Projection Display”, Proc. IEEE/LEOS Int. Conf. Opt. MEMS Appl. Conf., 25-26, 2006 also describes a mirror that can be moved around two axes, wherein the actuator for one of the rotary movements has large meander structures that are not very compact, only allow a low resonant frequency and can also be sensitive to shock. The publication H. Yu et al, “Optimization of MOEMS Projection Module Performance with Enhanced Piezoresistive Sensitivity”, Micromachines 2020, 11, 651 describes an electromagnetically driven mirror.

At least one object of certain embodiments is to provide a piezoelectric mirror component. At least one further object of certain embodiments is to provide a method for operating a piezoelectric mirror component. It is at least a further object of certain embodiments to provide a projection device with a piezoelectric mirror component.

These objects are solved by subject-matters and a method according to the independent patent claims. Advantageous embodiments and further developments of the subjects-matters and the method are characterized in the dependent claims and become further apparent from the following description and the drawings.

### SUMMARY

According to at least one embodiment, a piezoelectric mirror component, which may also be referred to as a mirror component for short in the following, has a mirror element, a piezoelectric drive ring and a frame element. The drive ring surrounds the mirror element and is connected to the mirror element via at least one first torsion spring element. The frame element is connected to the drive ring via at least a second torsion spring element. The mirror element, the drive ring and the frame element as well as the torsion spring elements can, in particular, be aligned along a plane in an idle state of the mirror component.

At least on the drive ring a piezoelectric layer is applied, which is arranged between a first electrode and a second electrode. The piezoelectric layer can have one or more piezoelectric materials. Particularly preferably, the piezoelectric layer has a piezoelectric material based on lead zirconate titanate (PZT) or is made of it.

At least the second electrode is preferably patterned into a plurality of actuation regions. This means that the second electrode can have a plurality of regions that can be controlled independently of one another. The first electrode and/or the piezoelectric layer can be applied contiguously or can also be at least partially patterned. Thus, the first electrode and the second electrode that is patterned into a plurality of actuation regions are preferably applied to the drive ring, with the piezoelectric layer being arranged between the first and second electrodes. Particularly preferably, the first electrode, the piezoelectric layer and the second electrode are applied in this order. By applying an electrical voltage between the first electrode and at least one actuation region of the second electrode, a mechanical deformation of the piezoelectric layer and thus of the drive ring can be achieved in a partial region via the inverse piezo effect, wherein a force can be exerted on the drive ring and/or the mirror element. Each of the actuation regions can thus form a piezoelectric element with the piezoelectric layer and the first electrode, through which a partial region of the mirror component can be moved. By applying an alternating current signal with an oscillating electrical voltage, an oscillating force can be exerted which can cause an oscillating deformation. This can cause at least part of the mirror component to oscillate.

The at least one first torsion spring element and the at least one second torsion spring element can be embodied in particular as so-called torsion beams. In other words, each of the torsion spring elements is elongated in the form of a beam with a longitudinal direction which, in particular during operation of the mirror component, can perform a torsional movement about an axis of rotation, the axis of rotation preferably corresponding substantially to the longitudinal direction of the beam.

The at least one first torsion spring element preferably extends from the mirror element to the drive ring and defines a first axis of rotation. If the mirror element and the drive ring are rotated relative to one another about the first axis of rotation, the end of the at least one first torsion spring element that is closer to the mirror element rotates relative to the end of the at least one first torsion spring element that is closer to the drive ring. In particular, a suitable actuation of actuation regions of the second electrode with a first alternating current signal with a first frequency can cause the mirror element to be set into a first rotational oscillation with the first frequency, wherein a restoring force, which is preferably linearly dependent on the angle of rotation, is exerted on the mirror element via the at least one first torsion spring element. Such a rotational oscillation on at least one torsion spring element is also referred to below as a torsional oscillation. The first rotational oscillation can therefore also be referred to as first torsional oscillation.

The at least one second torsion spring element preferably extends from the drive ring to the frame element and defines a second axis of rotation. If the frame element and the drive ring are rotated relative to each other about the second axis of rotation, the end of the at least one second torsion spring element closer to the frame element rotates relative to the end of the at least one second torsion spring element closer to the drive ring. In particular, suitable actuation of actuation regions of the second electrode with a second alternating current signal with a second frequency can cause the drive ring to be set into a second rotational oscillation with the second frequency, wherein a restoring force, which is preferably linearly dependent on the angle of rotation, is exerted on the drive ring via the at least one second torsion spring element. In particular, the mirror element can perform the second rotational oscillation together with the drive ring. The described second rotational oscillation can also be referred to as a second torsional oscillation.

Particularly preferably, the first torsion spring element and the second torsion spring element are arranged rotated by 90° to each other so that the first axis of rotation for the first torsional oscillation and the second axis of rotation for the second torsional oscillation are perpendicular to each other. This ensures that the first and second torsional oscillations are as independent of each other as possible.

According to a further embodiment, the first electrode is also at least partially applied to the frame element. Furthermore, the piezoelectric layer can also be at least partially applied to the frame element. In addition, the second electrode can also be at least partially applied to the frame element. Furthermore, the first electrode and/or the piezoelectric layer can also be applied to the at least one second torsion spring element. Furthermore, the at least one second torsion spring element can be free of the second electrode. Particularly preferably, the at least one first torsion spring element and the mirror element are free of the first electrode, the piezoelectric layer and the second electrode.

According to a further embodiment, the second electrode is patterned on the frame element in a plurality of actuation regions. In particular, the second electrode can be applied in an actuation region of the frame element surrounded by an edge part of the frame element. As a result, it may be possible to provide further actuation regions on the frame element in addition to the actuation regions on the drive ring, by means of which a force can be exerted on the drive ring, for example, with suitable actuation.

Furthermore, contact elements for controlling the first and second electrodes can be provided on the frame element, for example on an edge part of the frame element. Actuation regions on the drive ring and/or on the frame element can be connected to contact elements on the frame element via conductor tracks that run over the at least one second torsion spring element. Alternatively, it may also be possible to dispense with conductor tracks and bond directly to the electrodes. This can make it possible to avoid parasitic resistances and capacitances that can occur in connection with conductor tracks.

In a method for operating the piezoelectric mirror component, as described above, the mirror element is preferably set into a first torsional oscillation by means of a first electrical alternating current signal with a first frequency, which acts on first actuation regions. The drive ring, preferably together with the mirror element, is set into a second torsional oscillation by means of a second electrical alternating current signal with a second frequency, which acts on second actuation regions. In particular, the actuation with the first alternating current signal and the actuation with the second alternating current signal can take place simultaneously, so that the mirror element in particular can perform the two torsional oscillations simultaneously, with the mirror element oscillating relative to the drive ring about the first axis of rotation at the first frequency and the drive ring oscillating together with the mirror element relative to the frame element about the second axis of rotation at the second frequency. The first frequency and the second frequency can in particular be resonant frequencies or at least lie close to a respective resonant frequency, which can be dependent on the respective oscillating parts of the mirror component and their geometric configurations. The first frequency and the second frequency are particularly preferably different.

According to a further embodiment, a projection device has a laser light source and the piezoelectric mirror component. The mirror component can deflect laser light emitted by the laser light source during operation. As a result of the torsional oscillations of the mirror element described above, the deflected laser light can be used to sweep an image region that can be perceived by an observer. In other words, scanning can be achieved with the mirror component. Particularly preferably, so-called Lissajous scanning can be achieved with resonant or near-resonant torsional oscillations about the first axis of rotation and about the second axis of rotation, which are particularly preferably perpendicular to each other.

The features and embodiments described above and below relate equally to the piezoelectric mirror component, to the method for operating the piezoelectric mirror component and to the projection device with the piezoelectric mirror component.

According to a further embodiment, the drive ring has a first diameter along a first direction and a second diameter along a second direction perpendicular to the first direction, wherein the first diameter is different from the second diameter. Particularly preferably, the first diameter is larger than the second diameter. Thus, the drive ring does not have a circular shape. In particular, the drive ring can have an elliptical shape or at least approximate an elliptical shape.

The drive ring can be bounded by an inner edge facing the mirror element and an opposite outer edge in directions along the plane spanned by the first and second directions, wherein the inner and outer edges can each have an elliptical shape or at least approximate an elliptical shape. The shape of the outer edge can be defined by the first diameter and the second diameter. In other words, the aforementioned first and second diameters may be a first and second outer diameter of the drive ring. The inner edge may also have first and second diameters, which may also be referred to as first and second inner diameters, wherein the first inner diameter extends along the first direction and the second inner diameter extends along the second direction. The ratio of the first outer diameter to the second outer diameter may be the same or different from the ratio of the first inner diameter to the second inner diameter. If the ratios are different, this can mean in particular that the drive ring has a first width along the first direction and a second width along the second direction and the first width is different from the second width. For example, the first width can be smaller than the second width.

In particular, the at least one first torsion spring element can be arranged along the first direction, while the at least one second torsion spring element is arranged along the second direction. Particularly preferably, the drive ring is connected to the mirror element via two first torsion spring elements, which are arranged along a straight line along the first direction on two opposite sides of the mirror element. Furthermore, the drive ring is particularly preferably connected to the frame element via two second torsion spring elements, which are arranged along a straight line along the second direction on two opposite sides of the drive ring.

Each of the first torsion spring elements and each of the second torsion spring elements can have features which are described in each case in connection with the at least one torsion spring element and the at least one second torsion spring element. In particular, the mirror element can be connected to the drive ring exclusively by the first torsion spring elements, while the drive ring can be connected to the frame element particularly preferably exclusively via the second torsion spring elements.

According to a further embodiment, the mirror element has a mirror region and an edge region surrounding the mirror region, which is preferably partially separated from the mirror region by means of at least one cut-out. The mirror element can particularly preferably be circular, so that the at least one cut-out can have the shape of an arc. Particularly preferably, there can be two cut-outs which are opposite each other and which both have the shape of a circular arc.

Furthermore, the mirror region can also be elliptical and have a larger elliptical axis and a smaller elliptical axis. Preferably, the larger elliptical axis is oriented along the first direction and the smaller elliptical axes are oriented along the second direction. Alternatively, the larger elliptical axis can be oriented along the second direction and the smaller elliptical axis along the first direction. In the case of an elliptical mirror region, the cut-outs have the shape of elliptical arcs. The ratio of the larger elliptical axis to the smaller elliptical axis can preferably be greater than 1 or greater than or equal to 1.02 or greater than or equal to 1.04 or greater than or equal to 1.06 as well as less than or equal to 1.1 or less than or equal to 1.08 or less than or equal to 1.07.

The edge region can be connected to the mirror region via two connection regions. In other words, the two cut-outs can be separated from each other by the two connection regions. Particularly preferably, the connection regions are arranged along the second direction on two opposite sides of the mirror region, so that the two cut-outs can preferably lie opposite one another along the first direction.

According to a further embodiment, a reflective coating is applied to the mirror region. For example, the coating can be a metallic coating. Furthermore, a dielectric coating, such as a Bragg mirror, is also possible. The edge region and the connection regions can preferably be free of the reflective coating.

According to a further embodiment, the frame element surrounds the drive ring. In particular, the frame element can have a recess penetrating the frame element, in which the at least one second torsion spring element and the drive ring with the at least one first torsion spring element and mirror element arranged in the drive ring are arranged. The at least one second torsion spring element protrudes particularly preferably from the edge surface surrounding the recess and thus from the frame element into the recess. The recess preferably has a polygonal basic shape, which can be square, hexagonal or octagonal, for example. It is also possible for the recess to have the same size along the first and second directions. If the frame element has an actuation region, this can be directly adjacent to the recess. Furthermore, the actuation region can be partially separated from the edge part by means of at least one cut-out.

According to a further embodiment, the mirror element and the drive ring have a smaller thickness than at least one frame part of the frame element. Here and in the following, “thickness” can in particular mean an extension along a third direction, which is perpendicular to the first and second directions. If the frame element has an actuation region, the actuation region can preferably also have a smaller thickness than the frame part of the frame element.

The frame element, the drive ring, the mirror element and the torsion spring elements are particularly preferably formed in one piece. In particular, the frame element, the drive ring, the mirror element and the torsion spring elements can be made of silicon. A carrier, for example in the form of a silicon wafer or an SOI wafer (SOI: “silicon on insulator”), can be provided to manufacture the mirror component, which is patterned accordingly to form the frame element, the drive ring, the mirror element and the torsion spring elements. The electrodes and the piezoelectric layer and, depending on the design, insulator layers and/or conductor tracks, for example, can then be formed or applied to the patterned carrier.

According to a further embodiment, measures are provided in order to achieve a position determination of the mirror element and/or a position determination of the drive ring and/or a frequency determination of one or both torsional oscillations. For example, during operation of the piezoelectric mirror component, the second frequency can be measured in the first alternating current signal and the first frequency can be measured in the second alternating current signal. This can be achieved, for example, by using suitable frequency filters in the drive supply lines so that no additional lines are required. Furthermore, it may also be possible to provide third actuation regions in which a piezoelectric signal is measured via the piezoelectric effect. The third actuation regions can be provided in particular at suitable positions so that a good signal can be achieved.

Furthermore, at least two electrode elements can be provided for position and/or frequency measurement, which form a capacitor that has a variable capacitance when the mirror element is moved, in particular relative to the drive ring, or when the drive ring is moved, in particular relative to the frame element, wherein the capacitance of the capacitor is measured. With such a capacitive measurement, the zero crossing of the drive ring and/or the mirror element can also be determined in particular. In order to avoid a capacitive short circuit, the first electrode can be suitably patterned.

The electrode elements can, for example, be formed by conductor track parts. For example, a first electrode element can be arranged on the frame element, while a second electrode element is arranged on the drive ring adjacent to the first electrode element. When the drive ring is moved relative to the frame element, the distance between the electrode elements can change, as a result of which the capacitance of the capacitor formed by the electrode elements can change. Accordingly, for example, electrode elements can be arranged on the drive ring and the mirror element. It may also be possible, for example, to arrange two electrode elements on the frame element on opposite sides of the drive ring, so that the drive ring is located between the two electrode elements arranged on the frame element. The drive ring can then act like a moving dielectric between the electrode elements during a movement, wherein the capacitance of the capacitor formed as a result can change. Accordingly, two electrode elements can also be arranged on opposite sides of the mirror element on the drive ring.

Furthermore, it may also be possible for first and/or second actuation regions to be present, which are used alternately in a time-division multiplex process to drive the mirror element or the drive ring and to measure a piezoelectric signal.

Further advantages, advantageous embodiments and further developments become apparent from the embodiments described below in conjunction with the figures.

### BRIEF DESCRIPTION OF THE DRAWINGS

FIGS. 1A and 1B show schematic illustrations of a piezoelectric mirror component according to an embodiment,

FIGS. 2A to 2E show schematic illustrations of method steps of a method for manufacturing the piezoelectric mirror component according to FIGS. 1A and 1B,

FIGS. 3A and 3B show schematic illustrations of method steps of a method for operating the piezoelectric mirror component according to FIGS. 1A and 1B,

FIGS. 4A to 5E show simulation tests on the piezoelectric mirror component shown in FIGS. 1A and 1B,

FIGS. 6A and 6B show schematic illustrations of a piezoelectric mirror component according to a further embodiment,

FIGS. 7A to 7E show schematic illustrations of method steps of a method for manufacturing the piezoelectric mirror component according to FIGS. 6A and 6B,

FIGS. 8A to 8E show schematic illustrations of method steps of a method for operating the piezoelectric mirror component according to FIGS. 6A and 6B,

FIGS. 9A to 12E show simulation tests on the piezoelectric mirror component shown in FIGS. 6A and 6B,

FIGS. 13A and 13B show schematic illustrations of a piezoelectric mirror component according to a further embodiment,

FIGS. 14A to 14E show schematic illustrations of method steps of a method for manufacturing the piezoelectric mirror component according to FIGS. 13A and 13B,

FIG. 15 shows a schematic illustration of a method step of a method for operating the piezoelectric mirror component according to FIGS. 13A and 13B,

FIGS. 16A to 16E show simulation studies of the piezoelectric mirror component according to FIGS. 13A and 13B,

FIG. 17 shows a schematic illustration of a projection device according to a further embodiment,

FIGS. 18A to 18E show schematic illustrations of measures for determining the position and/or frequency of components of a piezoelectric mirror component according to some embodiments,

FIGS. 19A and 19B show schematic partial representations of a piezoelectric mirror component according to further embodiments.

### DETAILED DESCRIPTION

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

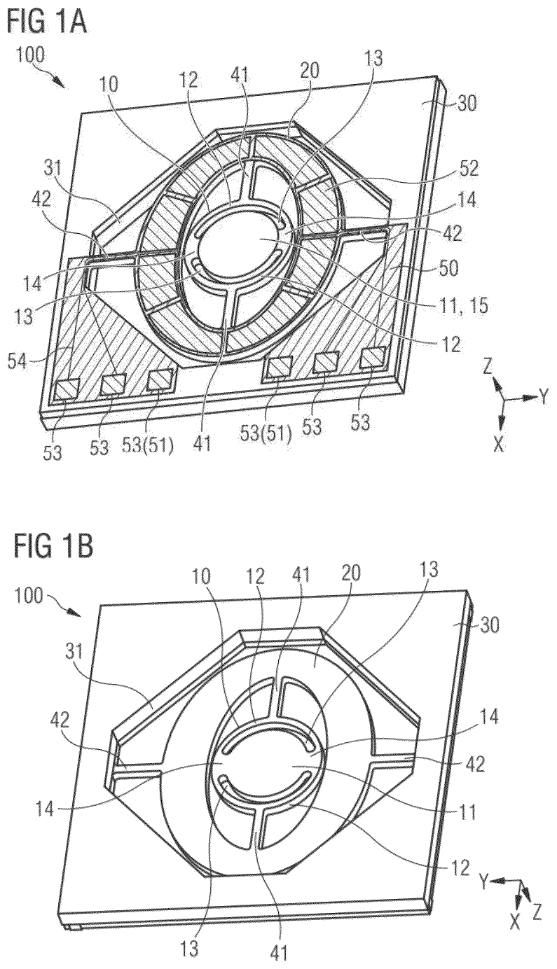

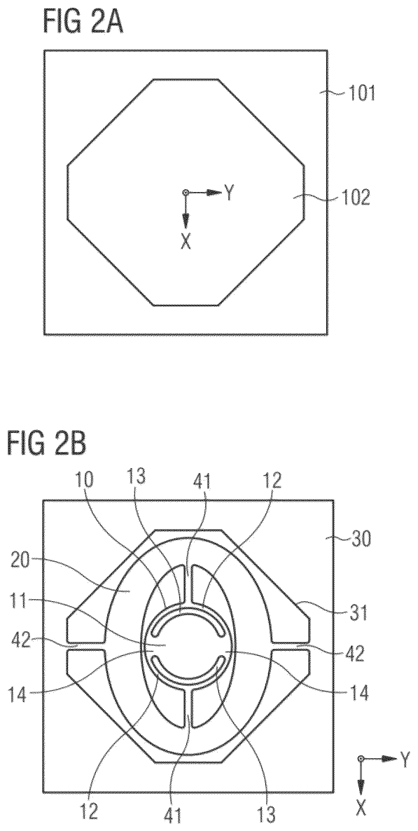

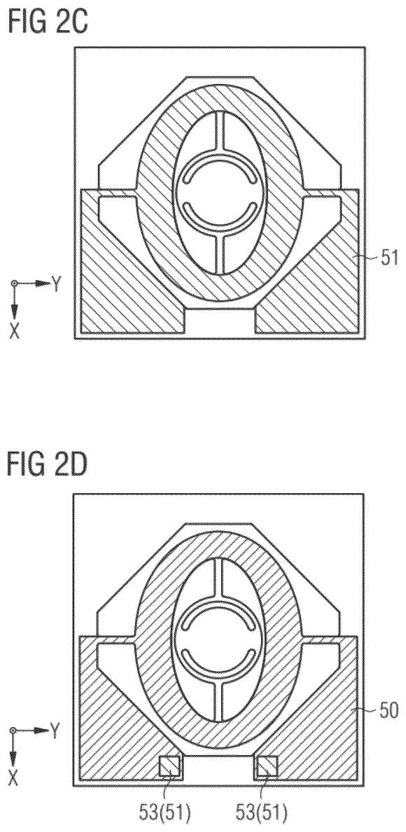

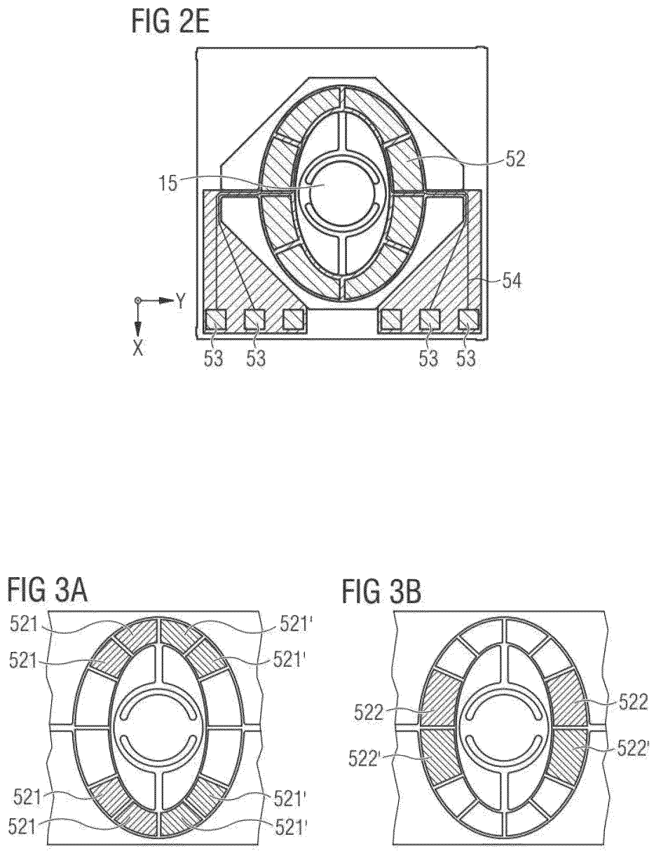

FIGS. 1A and 1B show schematic illustrations of a piezoelectric mirror component 100 according to an embodiment, wherein FIG. 1A shows a three-dimensional view of an top side of the mirror component 100 and FIG. 1B shows a three-dimensional view of a bottom side of the mirror component 100. FIGS. 2A to 2E show schematic illustrations of method steps of a method for manufacturing the piezoelectric mirror component 100 according to FIGS. 1A and 1B in views of the top side. The following description refers equally to FIGS. 1A and 1B and FIGS. 2A to 2E.

The piezoelectric mirror component 100 comprises a mirror element 10, a piezoelectric drive ring 20 and a frame element 30. The drive ring 20 surrounds the mirror element 10 and is connected to the mirror element 10 via at least one first torsion spring element 41. The frame element is connected to the drive ring via at least one second torsion spring element 42. The mirror element 10, the drive ring 20 and the frame element 30 as well as the torsion spring elements 41, 42 are aligned, in an idle state of the mirror component 100, along a plane which is spanned by a first direction, designated “x” in the figures, and a second direction perpendicular to the first direction, designated “y” in the figures. A piezoelectric layer 50 is applied to at least the drive ring 20 and is arranged between a first electrode 51 and a second electrode 52. The piezoelectric layer 50 preferably has a piezoelectric material based on lead zirconate titanate (PZT) or is made of it.

As indicated in FIG. 2A, a carrier 101, for example in the form of a silicon wafer or in the form of an SOI wafer with a carrier material made of an electrically insulating material and a silicon layer thereon, is provided for manufacturing the mirror component 100. In a region 102 in which the mirror element 10, the piezoelectric drive ring 20, the frame element 30 and the torsion spring elements 41, 42 are arranged, i.e. in the region in which the mirror component 100 is mechanically active, the carrier 101 is thinned from the bottom side. To form the mirror element 10, the drive ring 20 and the torsion spring elements 41, 42 in the region 102, the carrier is etched through, as shown in FIG. 2B, and thus patterned, so that a recess 31 is produced in the frame element 30 surrounding the drive ring 20, in which the mirror element 10, the piezoelectric drive ring 20, the frame element 30 and the torsion spring elements 41, 42 are arranged. The frame element 30, the drive ring 20, the mirror element 10 and the torsion spring elements 41, 42 are thus formed in one piece. The recess 31 preferably has a polygonal basic shape, which can be octagonal as shown. Furthermore, it may be possible for the recess 31 to have the same extension along the first and second directions.

As can also be seen in FIGS. 1A and 1B, the mirror element 10 and the drive ring 20 as well as the torsion spring elements 41, 42 have a smaller thickness than the frame element 30 as a result of the previously described thinning of the carrier 101, the thickness being measured in a third direction, designated “z” in the figures, which is perpendicular to the first and second directions. If necessary, an electrically insulating layer can be applied or formed on the top side of the carrier 101, for example with or made of silicon oxide or silicon nitride.

As shown, the drive ring 20 is connected to the mirror element 10 via two first torsion spring elements 41, which are arranged along a straight line along the first direction on two opposite sides of the mirror element 10. Furthermore, the drive ring 20 is connected to the frame element 30 via two second torsion spring elements 42, which are arranged along a straight line along the second direction on two opposite sides of the drive ring 20. This means that the suspension of the mirror element 10 on the drive ring 20 is rotated by 90° relative to the suspension of the drive ring 20 on the frame element 30.

The mirror element 10 has a mirror region 11 and an edge region 12 surrounding the mirror region 11, which is partially separated from the mirror region 11 by two cut-outs 13, which are produced by etching as part of the previously described formation of the mirror element 10, and is thus preferably at least partially mechanically decoupled. As shown, the mirror element 10 and the mirror region 11 preferably have a circular basic shape, so that the cut-outs 13 have the shape of circular arcs. The two cut-outs 13 are formed opposite each other along the first direction. The edge region 12 is connected to the mirror region 11 via two connection regions 14, so that the two cut-outs 13 are separated from one another by the two connection regions 14, which are arranged along the second direction on two opposite sides of the mirror region 11, and so that the connection regions are aligned rotated by 90° with respect to the first torsion spring elements 41.

The first electrode 51 and the piezoelectric layer 50 are applied contiguously to the drive ring 20, to the second torsion spring elements 42 and partially to the frame element 30, as can be seen in FIGS. 2C and 2D. Contact elements 53 are provided in the form of recesses in the piezoelectric layer 50, as indicated in FIG. 2D, so that the part of the first electrode 51 on the drive ring 20 can be contacted from the outside via the part of the first electrode 51 on the frame element 30.

On the piezoelectric layer 50, as shown in FIG. 2E, the second electrode 52 is applied to the drive ring 20. The second electrode 52 is patterned into a plurality of actuation regions which, as is explained further below, can be divided at least into first and second actuation regions, so that the second electrode 52 has a plurality of regions which can be driven independently of one another. For electrical contacting of the actuation regions of the second electrode 52, further contact regions 53 are applied to the frame element 30, which are electrically conductively connected to the actuation regions via conductor tracks 54, which are also applied to the piezoelectric layer 50.

Furthermore, as can also be seen in FIG. 2E, a reflective coating 15 is applied to the mirror region 11, which is preferably a metallic coating. A dielectric coating, such as a Bragg mirror, is also possible. The edge region 12 and the connection regions 13 remain free of the reflective coating 15.

The first torsion spring elements 41 and the second torsion spring elements 42 are embodied as so-called torsion beams and have an elongate shape with a longitudinal direction, which runs along the first direction in the case of the first torsion spring elements 41 and along the second direction in the case of the second torsion spring elements 42. During operation of the mirror component 100, the torsion spring elements 41, 42 can each perform a torsional movement about an axis of rotation, the axis of rotation preferably corresponding substantially to the longitudinal direction of the respective torsion spring element 41, 42. If the mirror element 10 is rotated relative to the drive ring 20 about the first axis of rotation defined by the first torsion spring elements 41, the first torsion spring elements 41 can preferably exert a restoring force on the mirror element 10 that is linearly dependent on the angle of rotation. If the drive ring 20 and thus also the mirror element 10 is rotated relative to the frame element 30 about the second axis of rotation defined by the second torsion spring elements 42, the second torsion spring elements 42 can preferably exert a restoring force on the drive ring 20 that is linearly dependent on the angle of rotation.

On the drive ring 20, the first electrode 51, the piezoelectric layer 50 and each of the actuation regions of the second electrode 52 form piezoelectric elements that can be actuated independently of one another. By applying an electrical voltage between the first electrode 51 and at least one actuation region of the second electrode 52, a mechanical deformation of the piezoelectric layer 50 and thus of the drive ring 20 can be achieved in a partial region via the inverse piezoelectric effect, wherein a force can be exerted on the drive ring 20 and/or the mirror element 10. By applying an alternating current signal with an oscillating electrical voltage, an oscillating force can be exerted, which can cause an oscillating deformation. This can cause at least part of the mirror component 100 to oscillate. FIGS. 3A and 3B show schematic illustrations of control schemes for method steps of a method for operating the piezoelectric mirror component 100 according to FIGS. 1A and 1B. For the sake of clarity, only the actuation regions of the second electrode are provided with reference signs in FIGS. 3A and 3B. Reference signs mentioned below that are not shown in FIGS. 3A and 3B refer to FIGS. 1A to 2E.

By controlling the first actuation regions 521 marked in FIG. 3A with a first alternating current signal with a first frequency and the first actuation regions 521′ with the first alternating current signal with the first frequency, but a phasing shifted by 180°, the mirror element 10 can be displaced in a first torsional oscillation relative to the drive ring 20 about the first axis of rotation formed by the first torsion spring elements 41. By activating the second actuation regions 522 marked in FIG. 3B with a second alternating current signal with a second frequency and the second actuation regions 522′ with the second alternating current signal with the second frequency, but with a phasing shifted by 180°, the drive ring 20 and thus also the mirror element 10 can be displaced in a second torsional oscillation relative to the frame element 30 about the second axis of rotation formed by the second torsion spring elements 42.

In particular, the control with the first alternating current signal and the control with the second alternating current signal take place simultaneously, so that the mirror element 10 and the drive ring 20 perform said torsional oscillations simultaneously, so that the mirror element 10 oscillates relative to the drive ring 20 about the first axis of rotation with the first frequency and at the same time the drive ring 20 together with the mirror element 10 oscillates relative to the frame element 30 about the second axis of rotation with the second frequency. The first frequency and the second frequency can particularly preferably be resonance frequencies of the torsional oscillations or at least be close to a respective resonance frequency, which are dependent on the geometric configurations of the elements of the mirror component. The first frequency and the second frequency are particularly preferably different. The first and second torsional oscillations can preferably be mechanically decoupled due to the arrangement of the first axis of rotation rotated by 90° relative to the second axis of rotation.

Different resonant frequencies can be achieved in particular by the non-circular design of the drive ring 40 as shown and by the fact that the first torsional oscillation is performed only by the mirror element 10, while the second torsional oscillation is performed by the drive ring 20 together with the mirror element 10. As can be seen in FIGS. 1A to 2E, the drive ring 20 has a first diameter along the first direction and a second diameter along the second direction, the first diameter being different from the second diameter. In particular, the first diameter is larger than the second diameter in the embodiment shown. Particularly preferably, the drive ring 20 has an elliptical shape as shown or at least a shape approximating an elliptical shape.

The drive ring 20 is bounded by an inner edge facing the mirror element 10 and an opposite outer edge in directions along the plane spanned by the first and second directions, wherein the inner and outer edges may each have an elliptical shape or at least approximate an elliptical shape. The shape of the outer edge can be defined by the aforementioned first and second diameters, which are thus a first and second outer diameter of the drive ring 20. The inner edge also has a first and a second diameter, which are thus a first and a second inner diameter of the drive ring 20, wherein the first inner diameter extends along the first direction and the second inner diameter extends along the second direction. The ratio of the first outer diameter to the second outer diameter can be the same or different to the ratio of the first inner diameter to the second inner diameter. If the ratios are different, the drive ring 20 may have a first width along the first direction and a second width along the second direction as shown, wherein the first width is different from the second width. For example, the first width can be smaller than the second width as shown.

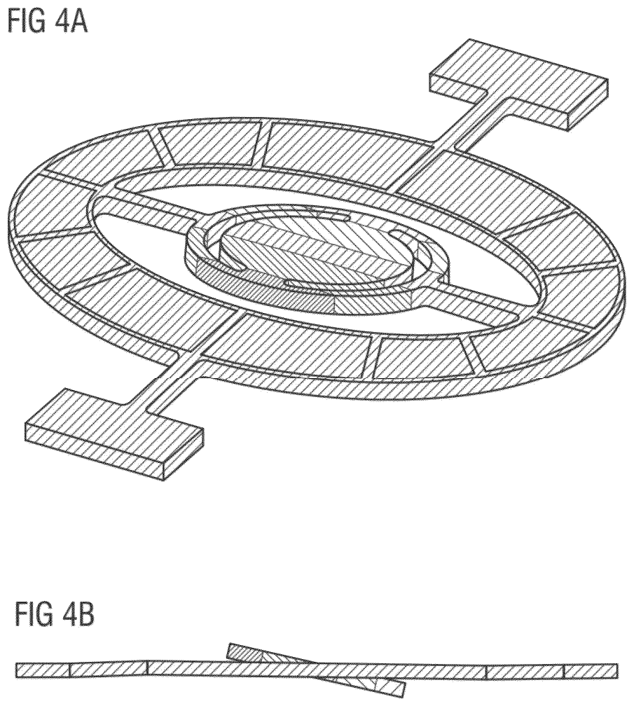

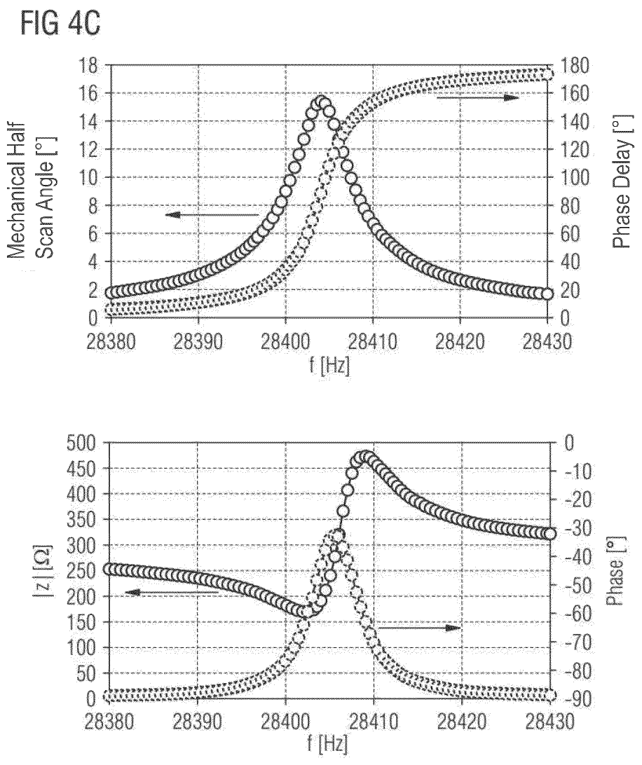

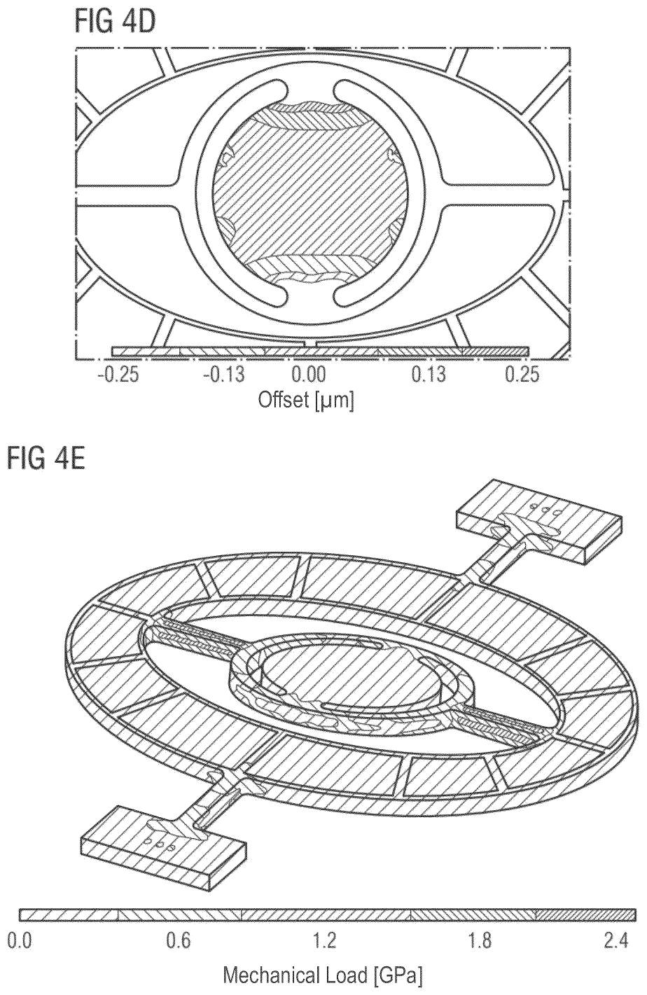

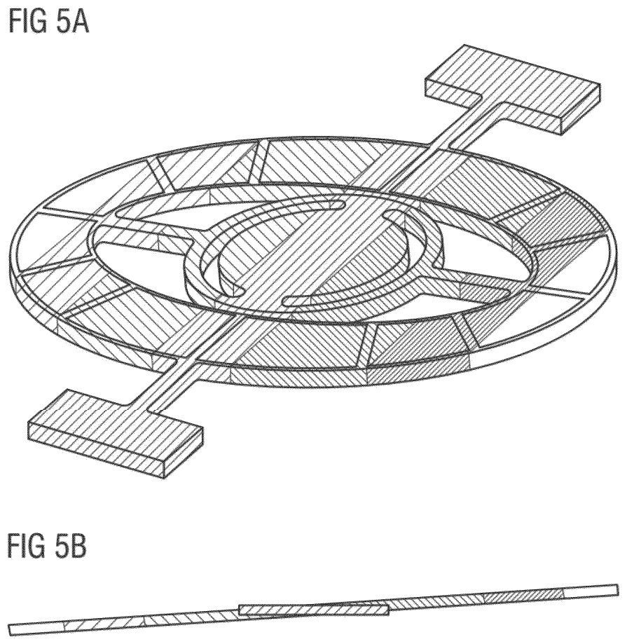

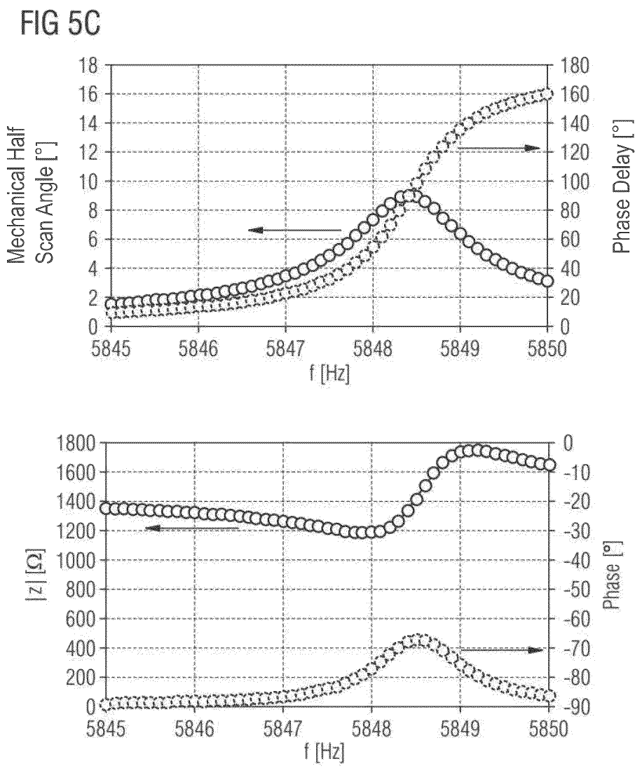

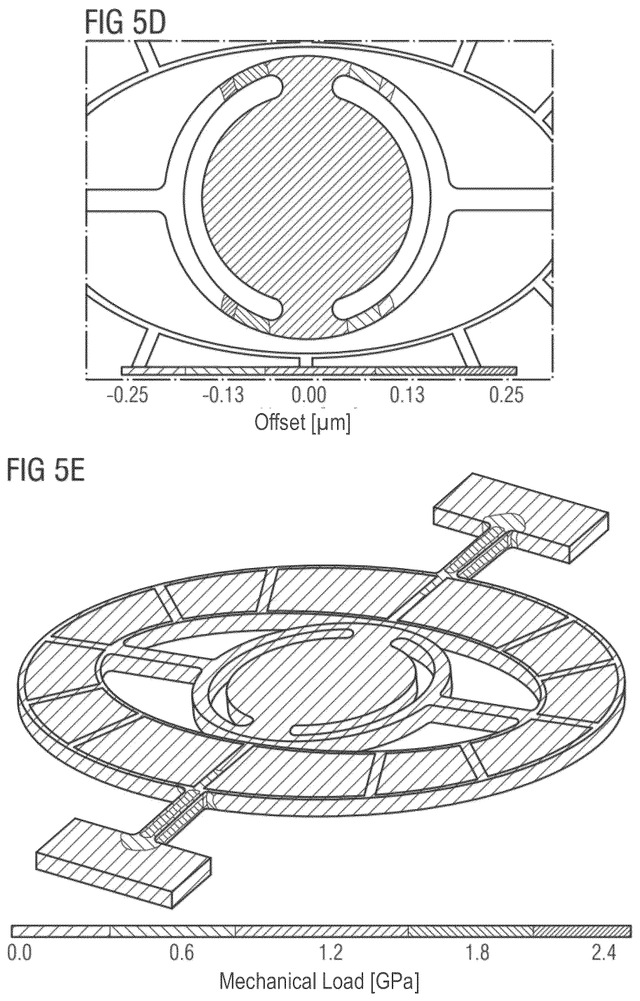

FIGS. 4A to 5E show simulation studies of the piezoelectric mirror component 100 according to the figures described above.

The following preferred parameters for the mirror component were assumed for this purpose:
Diameter of the mirror element: 1.7 mm
First outer diameter of the drive ring 20, i.e. larger outer diameter: 5.7 mm
Distance between the ends of the second torsion spring elements 42 adjacent to the frame element 30: 6.4 mm
Thickness of the moving parts of the piezoelectric mirror component, i.e. the elements inside the recess 31: 175 μm
Thickness of the piezoelectric layer: 1 μm
assumed attenuation: 10⁻⁴
Voltage of the alternating current signals: ±2 V
Square cross-section of the torsion spring elements 41, 42, i.e. thickness equals width
Neglecting the ESR (“equivalent series resistance”)

In FIGS. 4A and 4B, a three-dimensional view and a lateral view along the first direction show a relative rotation of the mirror element 10 with respect to the drive ring 20 due to the control for the first torsional oscillation described in connection with FIG. 3A.

FIG. 4C shows diagrams for simulations to investigate the mechanical performance (upper diagram) and the electrical performance (lower diagram) as a function of the first frequency of the applied first alternating current signal. For the mechanical performance, the mechanical half scan angle, i.e. the maximum achievable angle of rotation of the mirror element to one side from the neutral position due to the torsional oscillation, and the phase delay between the exciting first alternating current signal and the oscillating movement of the mirror element were investigated. The magnitude and phase of the complex resistance were investigated for the electrical performance. In the graphs, the arrows indicate which vertical axis refers to which curve. As can be seen from the diagrams, the resonant frequency of the first torsional oscillation is 28.4 kHz. The diagrams indicate a purely harmonic oscillation and thus a pure torsional oscillation mode without any significant non-linear behavior, and in particular there is no hysteresis behavior. The drive ring exhibits only very slight, in particular negligible, movement. The field of view (FoV) that can be achieved at resonance for the selected parameters is around 60°, which corresponds to a mechanical half scan angle of around 15°. By slightly detuning the first frequency from the resonance frequency, a reduction of the FoV can be achieved if necessary.

FIGS. 4D and 4E show, based on simulations, the torsion of the surface of the mirror element, indicated by an offset in micrometers, and the mechanical load on the mirror element in GPa during the first torsional oscillation at the resonant frequency. The torsion of the mirror surface during the oscillation is in the region of ±250 nm, with the highest values occurring only in the vicinity of the joint regions. The load for an FoV of 60° at resonance reaches maximum values of around 2.5 GPa in the first torsion spring elements. Such values are acceptable for silicon. By reducing the FoV, for example by a third to around 40°, the torsion and the load can be further reduced, as the magnitude of both effects is proportional to the scan angle.

In FIGS. 5A to 5E, corresponding to FIGS. 4A to 4E, results from simulations for the control described in connection with FIG. 3B are shown for the second torsional oscillation, with a view along the second direction being shown in FIG. 5B in comparison to FIG. 4B. A resonant frequency of 5.85 kHz results for the second torsional oscillation, wherein the second torsional oscillation is also a pure torsional oscillation mode around the second torsion spring elements without hysteresis behavior. The control ring moves together with the mirror element, so that a deflection of a laser beam can be achieved which is perpendicular to the deflection described in connection with FIGS. 4A to 4E, so that Lissajous scanning is possible by means of the first and second torsional oscillation. The achievable FOV with the selected parameters is 36°, which corresponds to a mechanical half scan angle of 9°. The torsion of the mirror surface during the oscillation is in the region of ±50 nm, wherein the highest values only occur in the edge regions of the mirror element and not on the mirror surface. The load for an FOV of 36° at resonance reaches maximum values of around 1.5 GPa in the second torsion spring elements. Such values are within an acceptable region for silicon, so that an FoV of 36° is possible for the second torsional oscillation.

Table 1 below summarizes the results of the simulations discussed in connection with FIGS. 4A to 5E:

TABLE 1

| Torsional | | |
|---|---|---|
| oscillation | first (fast mode) | second (slow mode) |
| Scan direction | y (i.e. parallel | x (i.e. parallel |
| | to the second | to the first |
| | direction) | direction) |
| Resonant | 28.4 | 5.85 |
| frequency (kHz) | | |
| Field of View (°) | 60 | 36 |
| Maximum load (GPa) | 2.5 | 1.5 |
| Torsion (nm) | ±250 nm | ±50 nm |

So while the first torsion spring elements enable a comparatively fast pure torsional oscillation mode of the mirror element, the second torsion spring elements enable a comparatively slower pure torsional oscillation mode of the drive ring together with the mirror element. Both oscillations are free of non-linear behavior and hysteresis.

In connection with the following figures, further embodiments are described which represent modifications of the mirror component explained in connection with the previous figures. The following description therefore essentially relates to the differences to the previous description.

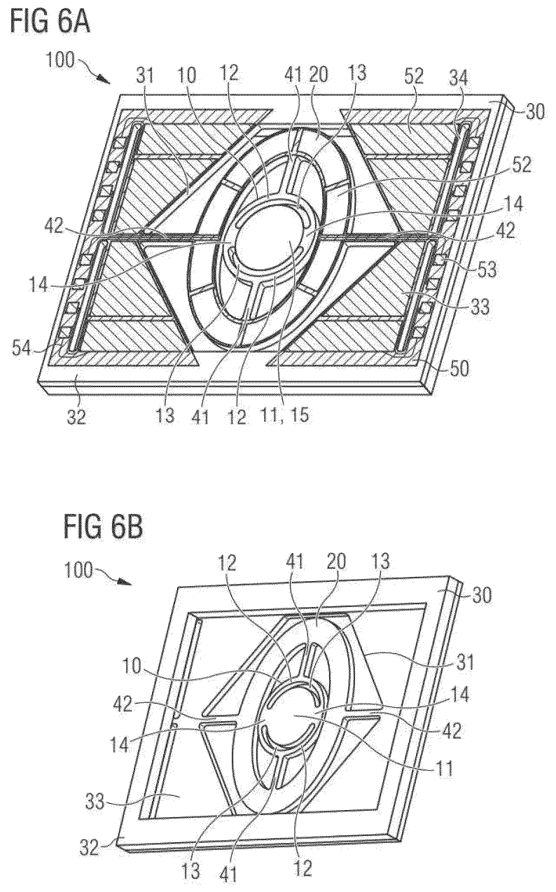

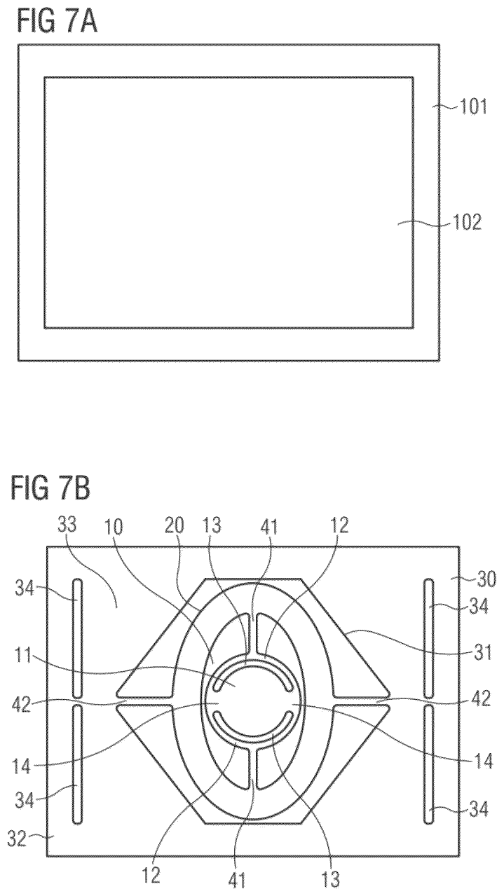

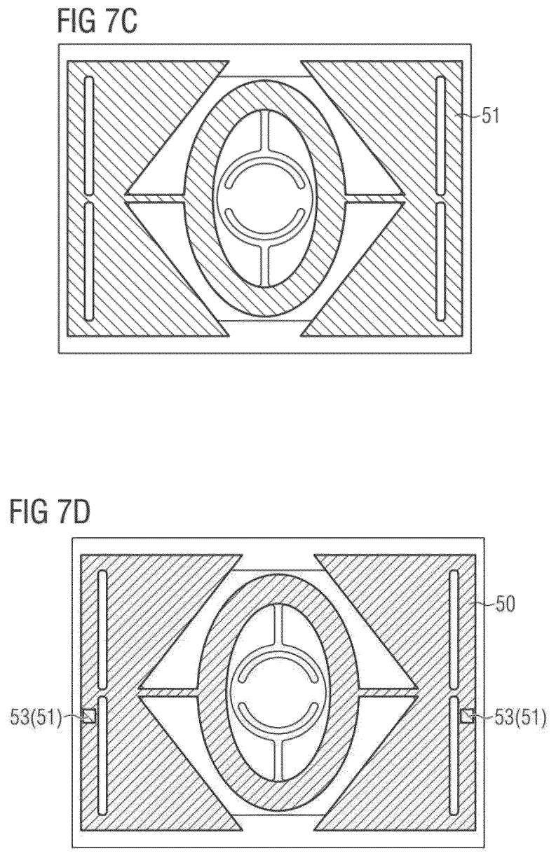

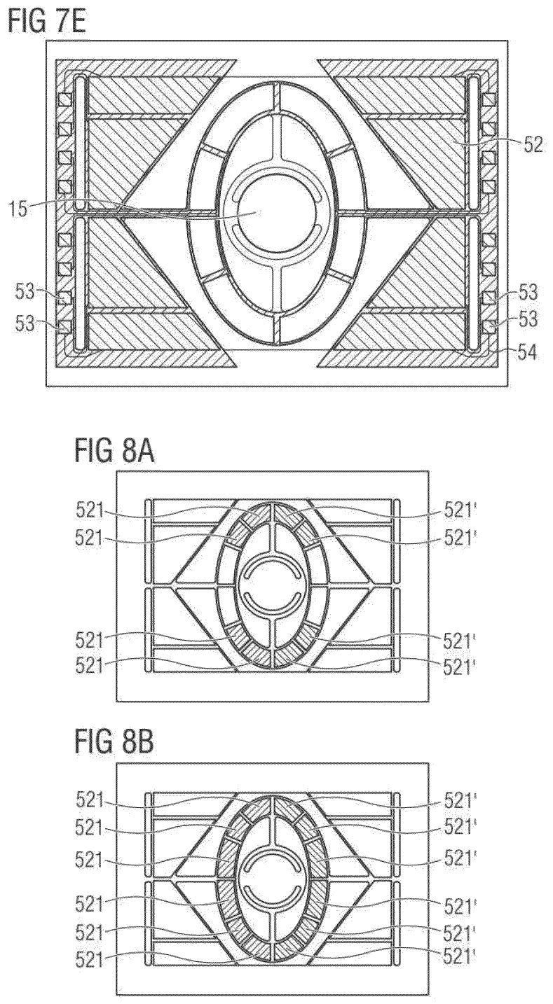

FIGS. 6A and 6B show schematic illustrations of a piezoelectric mirror component 100 according to a further embodiment, wherein the views in FIGS. 6A and 6B correspond to those in FIGS. 1A and 1B. FIGS. 7A to 7E show schematic illustrations of method steps of a method for manufacturing the piezoelectric mirror component 100 according to FIGS. 6A and 6B, wherein the views of FIGS. 7A to 7E correspond to those in FIGS. 2A to 2E. The following description refers equally to FIGS. 6A and 6B and FIGS. 7A to 7E.

In comparison with the mirror component described in connection with FIGS. 1A to 2E, the mirror component 100 of FIGS. 6A to 7E additionally has an actuation region 33 of the frame element 30 on the frame element 30, which is surrounded by an edge part 32 of the frame element 30. The actuation region 33 directly adjoins the recess 31, which can be hexagonal, for example, as shown, and, like the movable components of the mirror component 100 arranged in the recess 31, has a smaller thickness than the edge part 31. Furthermore, the actuation region 33 is partially separated from the edge part 32 by means of several cut-outs 34.

In addition to the drive ring 20, the second electrode 52 is also applied to the frame element 30 in the actuation region 33 and is patterned into a plurality of actuation regions. As a result, in addition to the actuation regions on the drive ring 20, further actuation regions can be provided on the frame element 30, through which a force can be exerted in particular on the drive ring 20 with a suitable actuation, which is described further below. As a result of the larger design shown with the additional actuation region 33, an additional or alternative drive for the second torsional oscillation of the drive ring 20 can thus be made possible compared to the previous embodiment.

As shown in FIG. 7A, to produce the mirror component 100 shown in FIGS. 6A and 6B, a larger region 102 of the support 101 is thinned from the bottom side. The region 102 corresponds to the region in which the mirror element 10, the piezoelectric drive ring 20, the frame element 30, the torsion spring elements 41, 42 and the actuation region 33 are arranged. To form the mirror element 10, the drive ring 20, the torsion spring elements 41, 42 and the actuation region 33 in the region 102, the carrier is etched through and patterned, as shown in FIG. 7B, so that the cut-outs 34 are produced in the frame element 30 in addition to the components in the recess 31. The non-thinned part of the frame element 30, which surrounds the mirror element 10, the piezoelectric drive ring 20, the torsion spring elements 41, 42, the actuation region 33 and the cut-outs 34, forms the edge part 32, wherein all the components mentioned are formed in one piece. The method steps shown in FIGS. 7C to 7E correspond to the method steps described in connection with FIGS. 2C to 2E, wherein the first electrode 51, the piezoelectric layer 50 and the second electrode 52 are also applied in the actuation region 33 of the frame element 30 to form additional piezoelectric elements. The contact elements 53 are separated from the actuation region 33 by the cut-outs 34 and are arranged on the edge part 32. As a result, the contact elements 53 are at least partially mechanically decoupled from the actuation region 33.

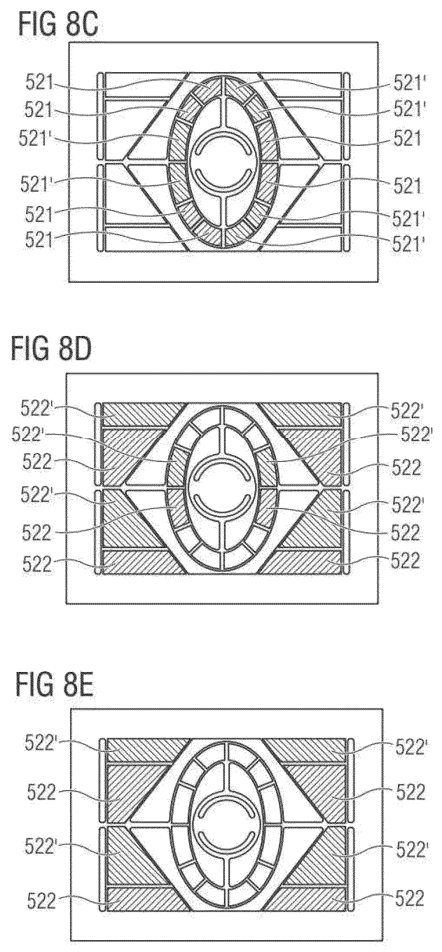

As explained in connection with FIGS. 3A and 3B, the first electrode 51, the piezoelectric layer 50 and each of the driving regions of the second electrode 52 on the drive ring 20 and the frame element 30 form piezoelectric elements which can be driven independently of each other. FIGS. 8A to 8E show schematic illustrations of exemplary drive schemes via first and second actuation regions 521, 521′, 522, 522′ for a method for operating the piezoelectric mirror component 100 according to FIGS. 6A to 7E.

In FIGS. 8A to 8C, first actuation regions 521 and 521′ are indicated, wherein the first actuation regions 521 are driven with a first alternating current signal with a first frequency and the first actuation regions 521′ are driven with the first alternating current signal with the first frequency, but with a phasing shifted by 180°, in order to set the mirror element 10 into a first torsional oscillation relative to the drive ring 20 about the first axis of rotation formed by the first torsion spring elements 41. FIGS. 8D and 8E show correspondingly second actuation regions 522 and 522′, wherein the second actuation regions 522 are controlled with a second alternating current signal with a second frequency and the second actuation regions 521′ are controlled with the second alternating current signal with the second frequency, but with a phasing shifted by 180°, in order to set the drive ring 20 together with the mirror element 10 into a second torsional oscillation relative to the frame element 30 about the second axis of rotation formed by the second torsion spring elements 42. In particular, the actuation scheme of FIG. 8A in combination with the actuation scheme of FIG. 8D and one of the actuation schemes of FIGS. 8B and 8C in combination with the actuation scheme of FIG. 8E can be used here, so that the actuation regions of the second electrode 52 can be clearly assigned to one of the two torsional oscillations.

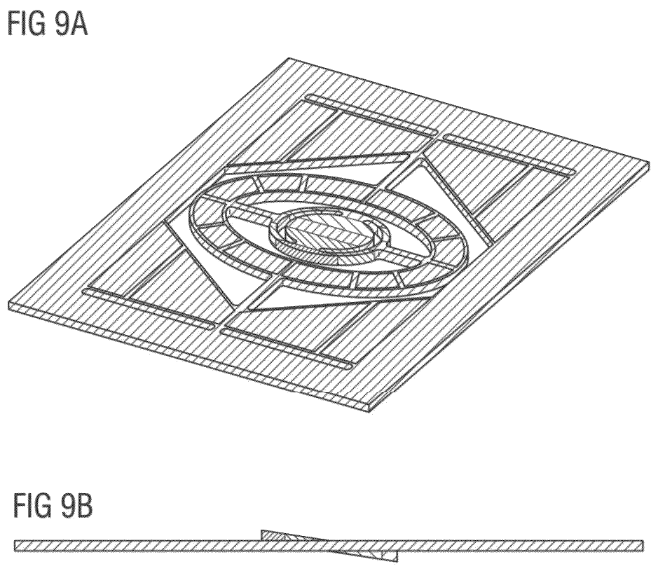

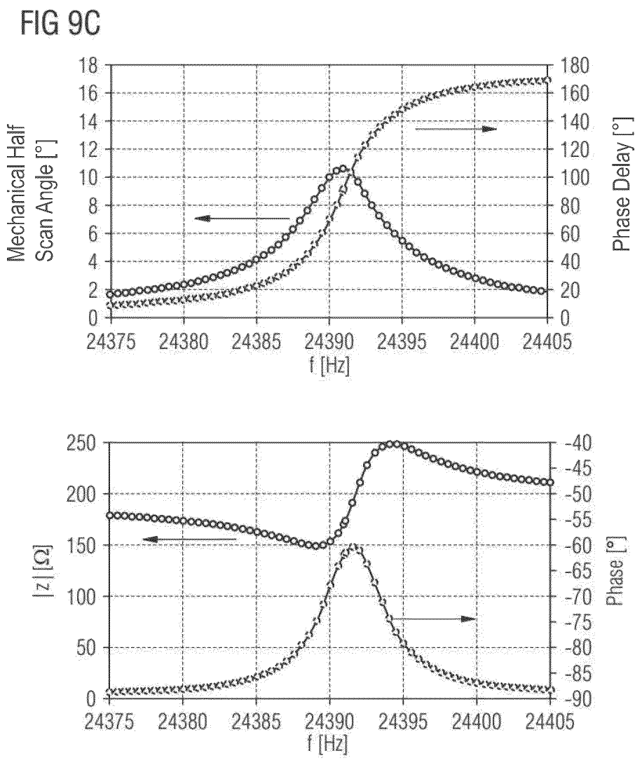

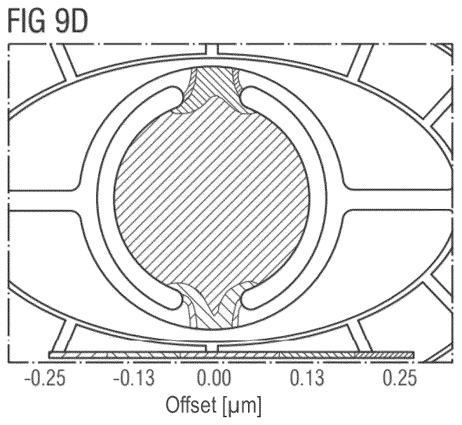

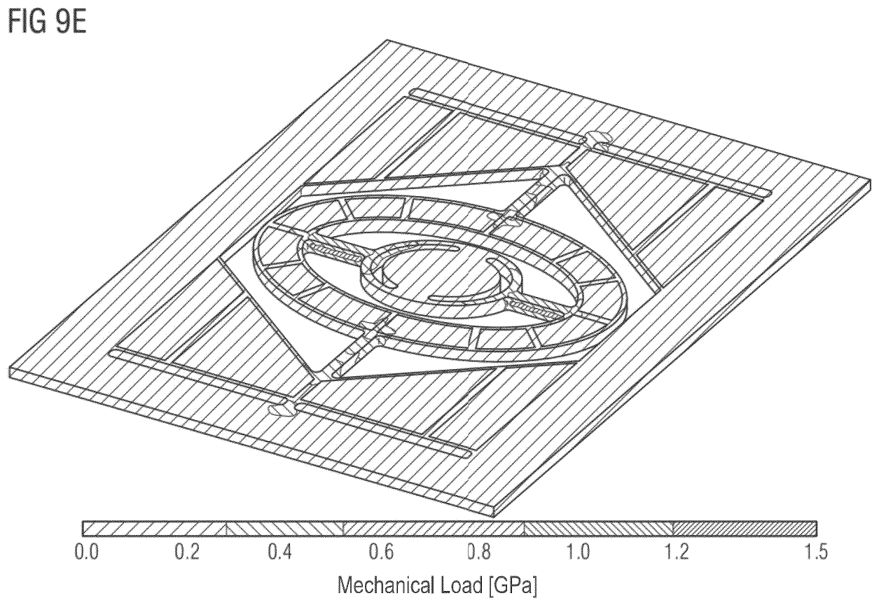

FIGS. 9A to 12E show simulation tests such as those explained in connection with FIGS. 4A to 5E, wherein in addition to the preferred parameters assumed above in connection with FIGS. 4A to 5E, the dimensions of the mirror component including the frame element were assumed to be approximately 11×8 mm². All simulation tests resulted in pure torsional oscillation modes without hysteresis behavior.

FIGS. 9A to 9E refer to the control shown in FIG. 8A for generating the first torsional oscillation. This results in a resonant frequency of 24.39 kHz and an FoV of approximately 42°, which corresponds to a mechanical half scan angle of approximately 10.7°. The torsion of the mirror region during the oscillation is ±23.8 nm, the mechanical load is sufficiently low.

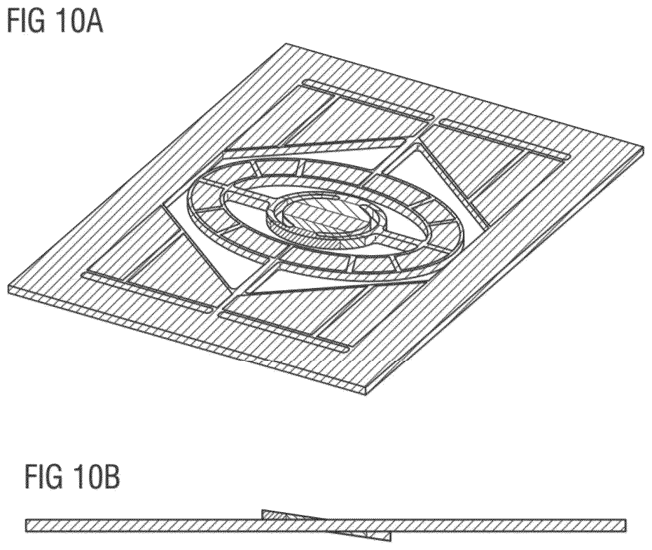

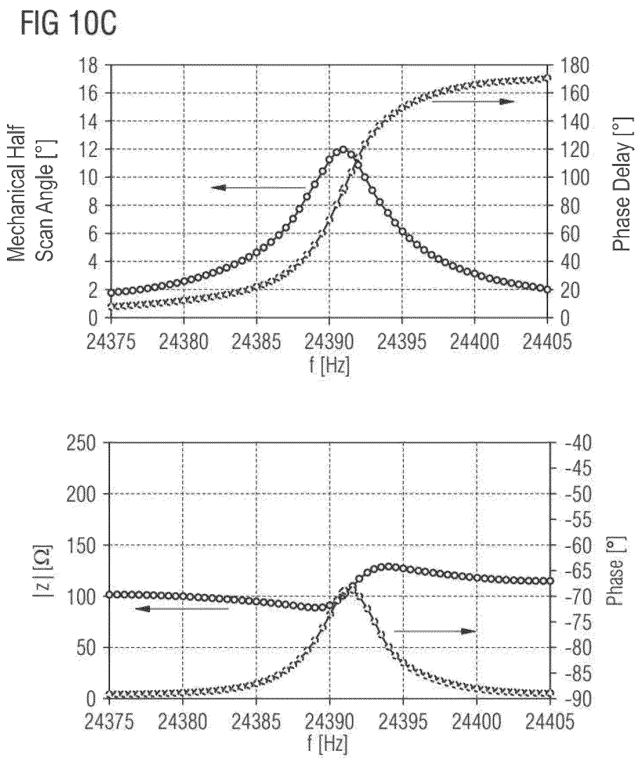

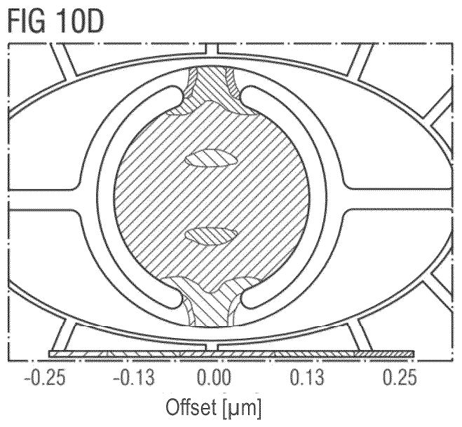

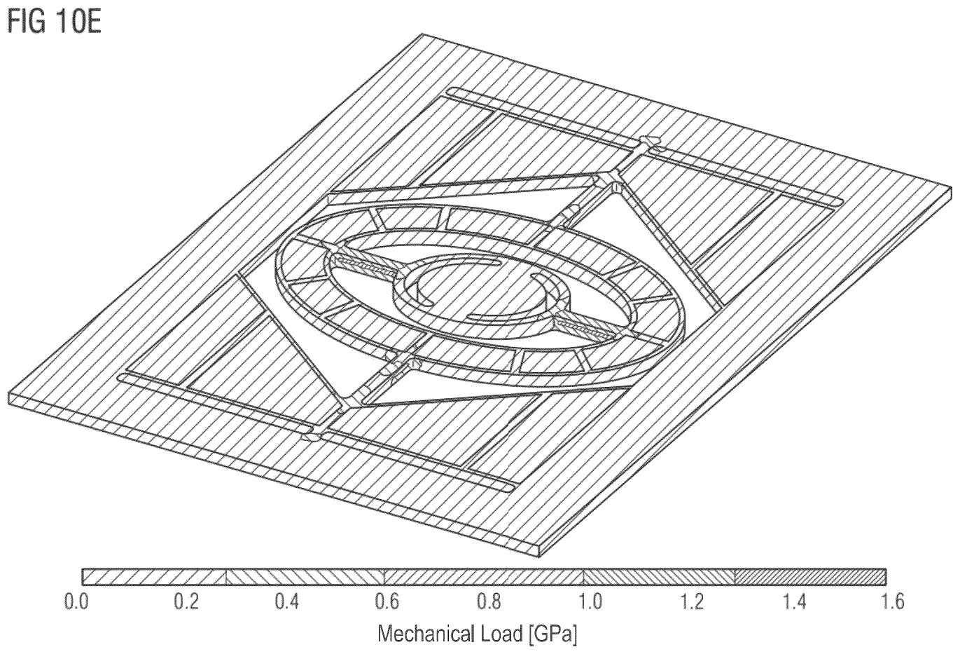

FIGS. 10A to 10E refer to the control shown in FIG. 8B for generating the first torsional oscillation. The resonant frequency, which is defined by the mechanical boundary conditions, is 24.39 kHz as in the case of FIG. 8A, but an FoV of 48° is achieved, which corresponds to a mechanical half scan angle of 12°. The distortion of the mirror surface during oscillation is ±26.8 nm, the mechanical load is sufficiently low.

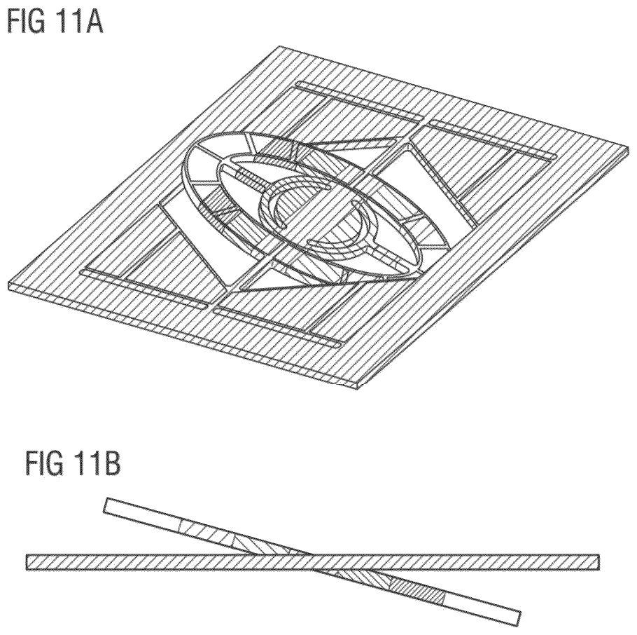

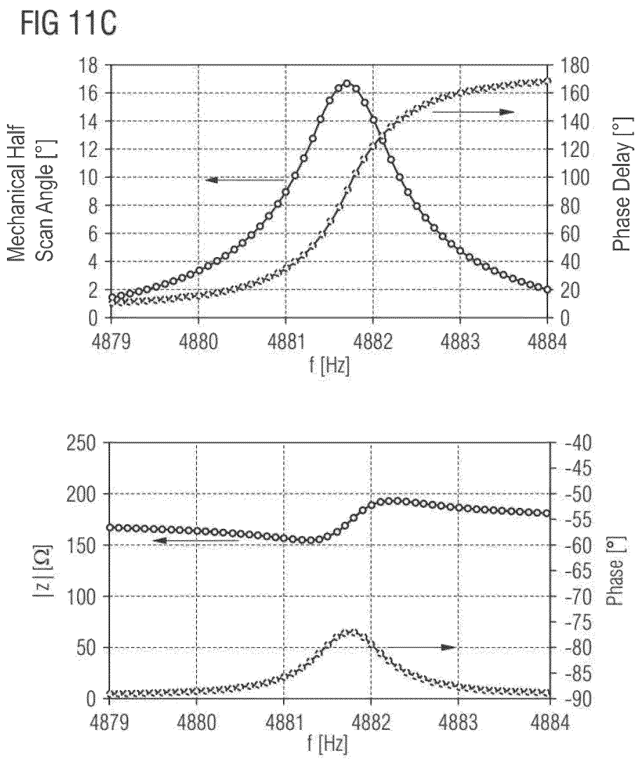

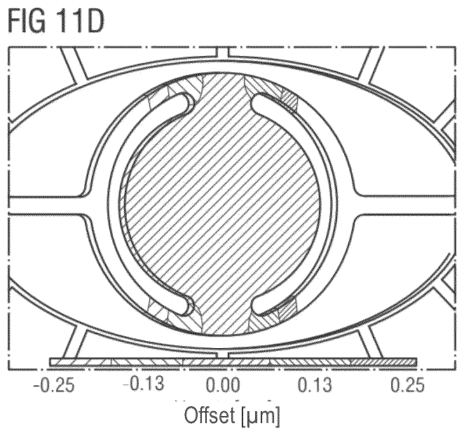

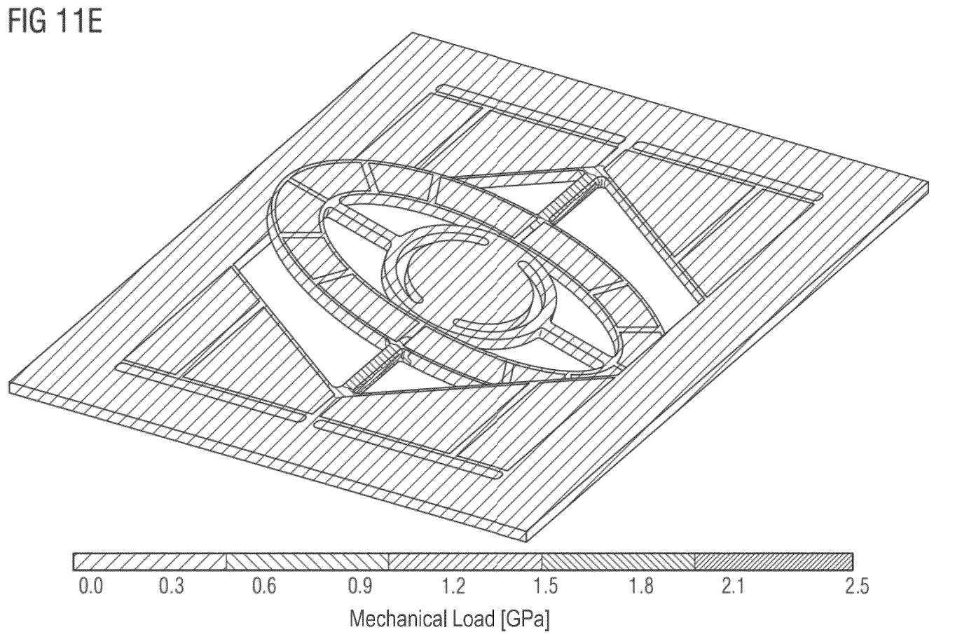

FIGS. 11A to 11E refer to the control shown in FIG. 8D for generating the second torsional oscillation. This results in a resonant frequency of 4.88 kHz and an FoV of approximately 75°, which corresponds to a mechanical half scan angle of approximately 18.7°. The torsion of the mirror region during the oscillation is ±7.6 nm, the mechanical load is sufficiently low.

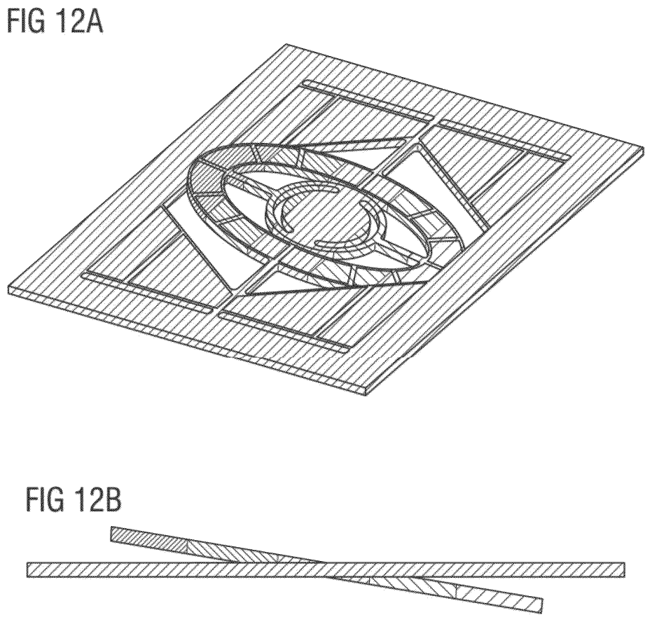

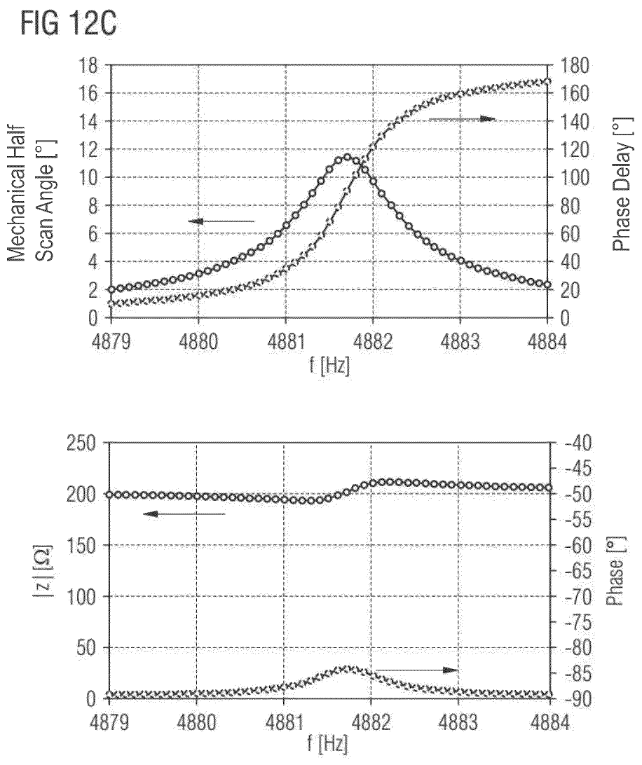

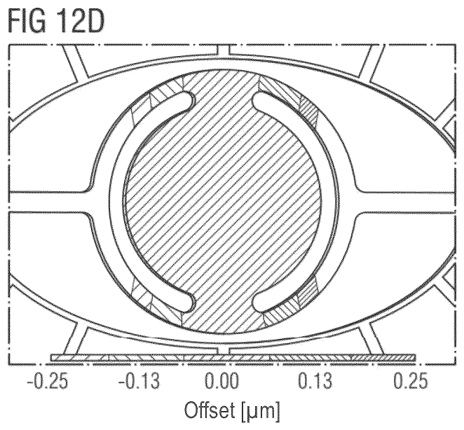

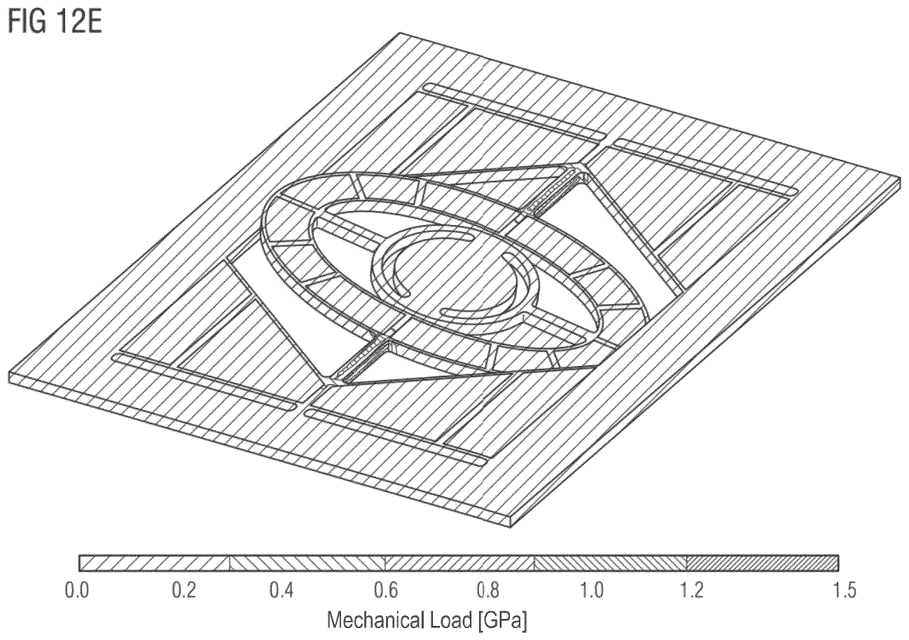

FIGS. 12A to 12E refer to the control shown in FIG. 8E for generating the second torsional oscillation. This again results in a resonant frequency of 4.88 kHz and an FoV of approximately 45°, which corresponds to a mechanical half scan angle of approximately 11.4°. The torsion of the mirror region during the oscillation is ±4.5 nm, the mechanical load is sufficiently low.

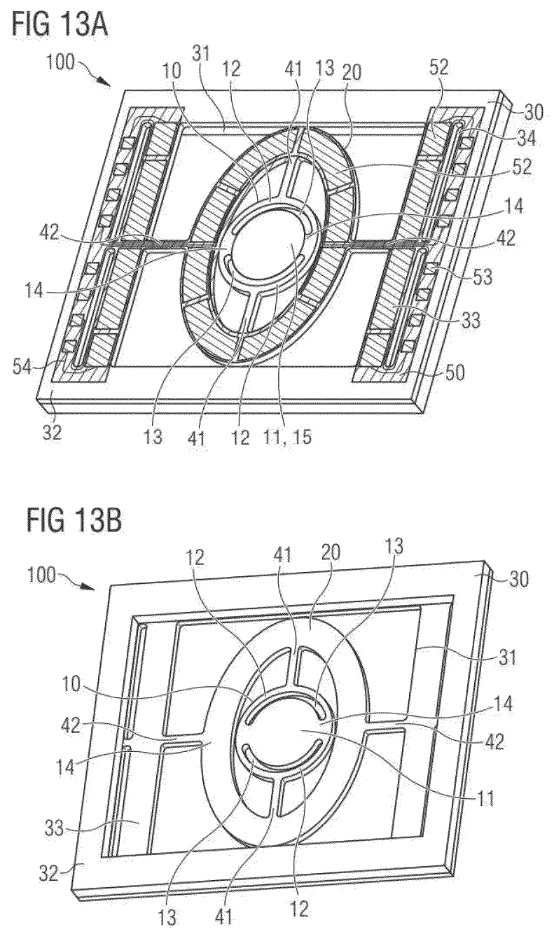

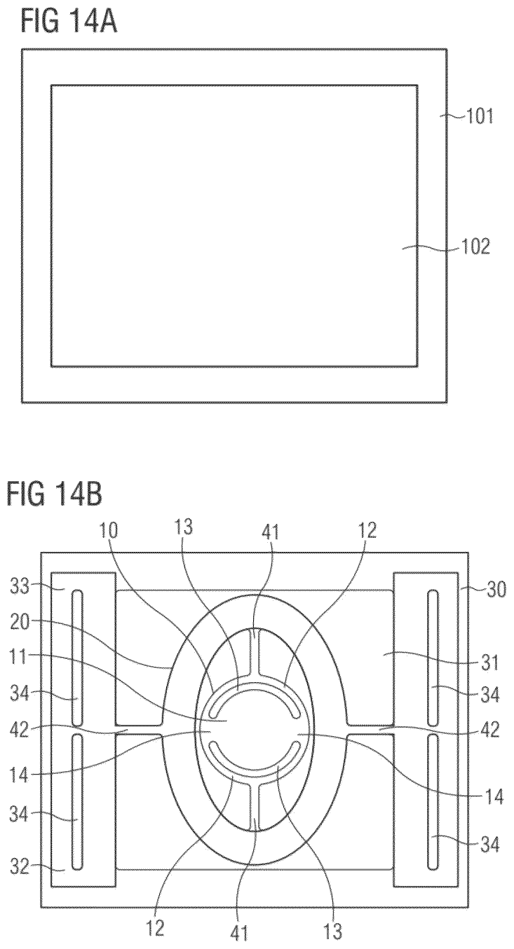

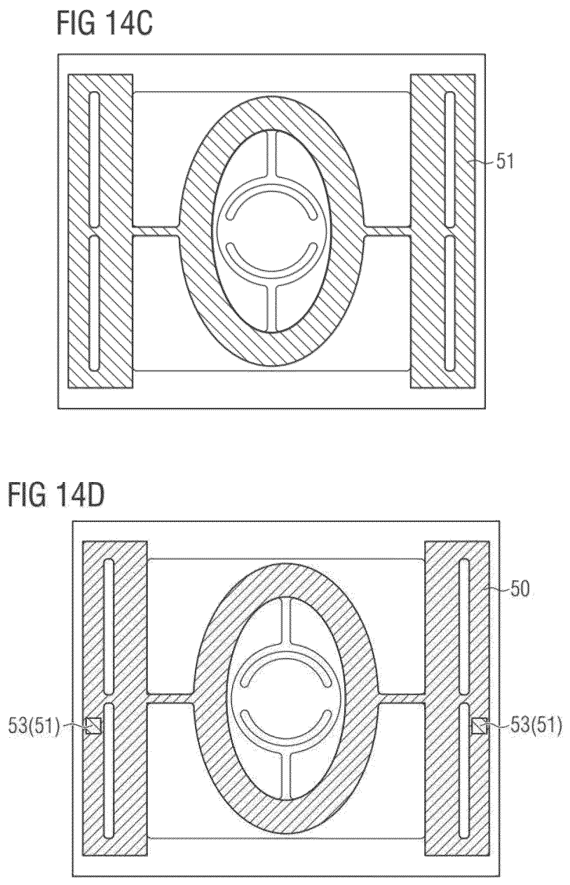

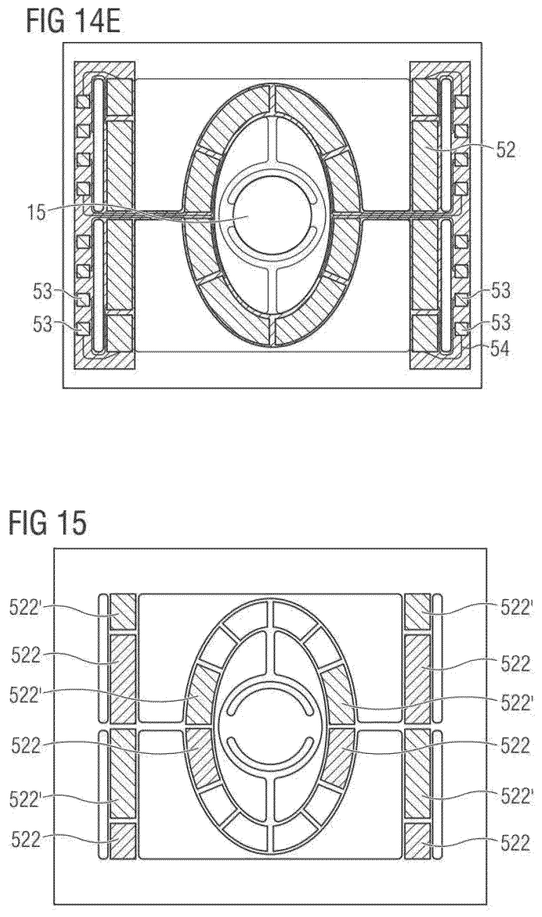

FIGS. 13A and 13B show schematic illustrations of a piezoelectric mirror component 100 according to a further embodiment, which forms a modification of the mirror component described in connection with FIGS. 6A to 7E. FIGS. 14A to 14E show schematic illustrations of method steps of a method for manufacturing the piezoelectric mirror component 100 according to FIGS. 13A and 13B and correspond to the method steps described in connection with FIGS. 7A to 7E. The following description refers equally to FIGS. 13A and 13B and FIGS. 14A to 14E.

Compared to the embodiment of FIGS. 6A to 7E, the embodiment for the mirror component 100 shown in FIGS. 13A to 14E has a smaller actuation region 33 with more rectangular shapes. In this embodiment, the recess 31 is quadrangular and preferably square.

FIG. 15 shows a schematic illustration of an exemplary control scheme via second actuation regions 522, 522′ for a method for operating the piezoelectric mirror component 100 according to FIGS. 13A to 14E, wherein the second actuation regions 522 are controlled with a second alternating current signal with a second frequency and the second actuation regions 522′ are controlled with the second alternating current signal with the second frequency, but with a phasing shifted by 180°, in order to set the drive ring 20 together with the mirror element 10 into a second torsional oscillation relative to the frame element 30 about the second axis of rotation formed by the second torsion spring elements 42. The control scheme shown in FIG. 8A, for example, can be used to generate the first torsional oscillation.

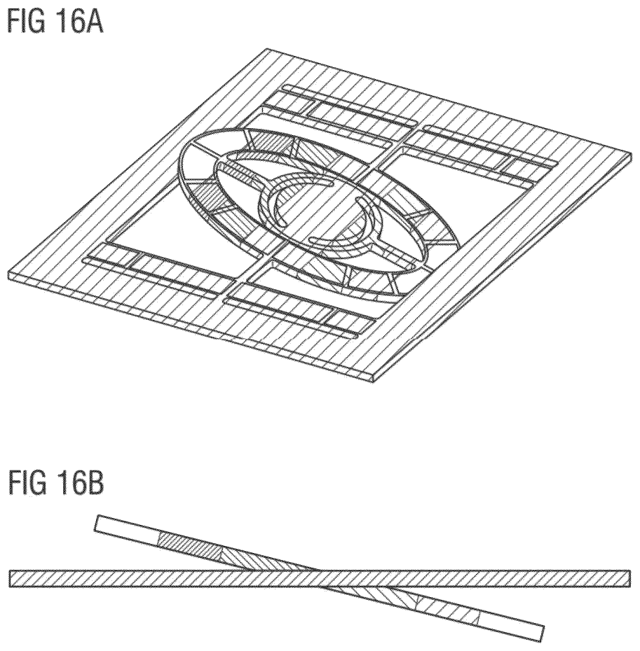

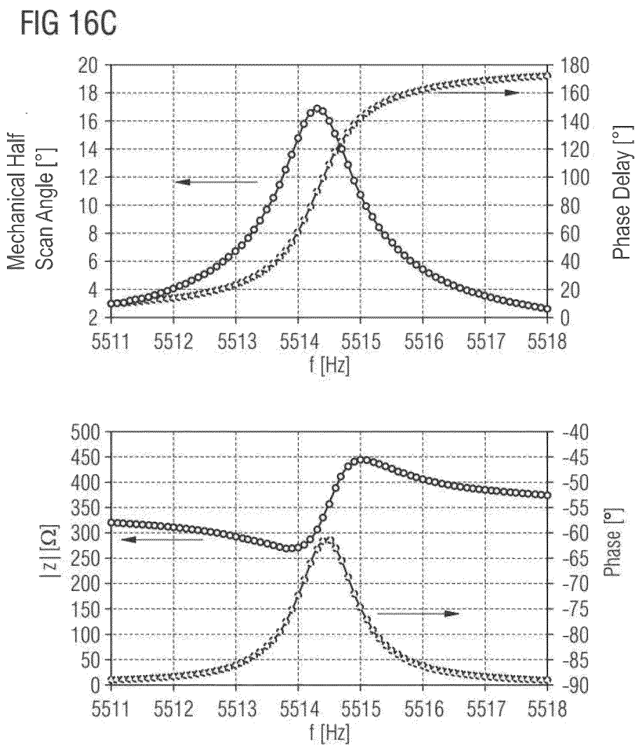

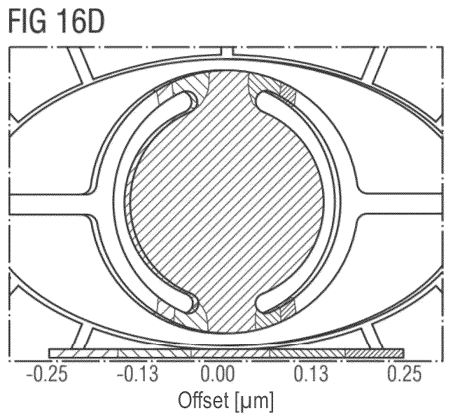

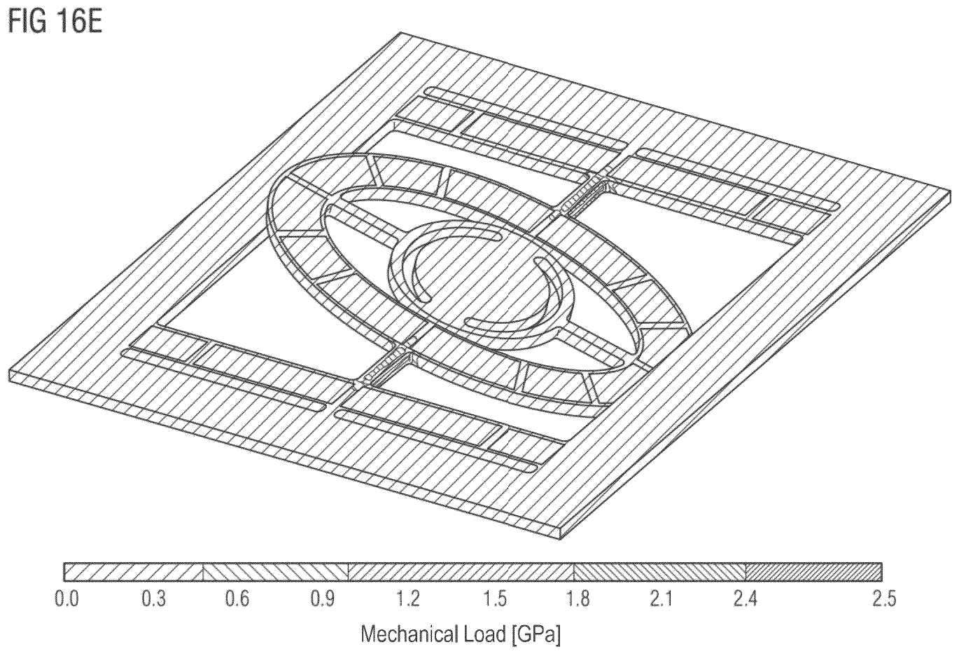

FIGS. 16A to 16E show simulation tests such as those explained in connection with FIGS. 4A to 5E, which relate to the control system indicated in FIG. 15. The simulation tests resulted in a pure torsional oscillation mode without hysteresis behavior for the second torsional oscillation investigated. This has a resonance frequency of 5.51 kHz and an FoV of 67°, which corresponds to a mechanical half scan angle of approximately 17.8°. The torsion of the mirror region during the oscillation is ±7.6 nm, the mechanical load is sufficiently low.

The piezoelectric mirror component described above according to some preferred embodiments has piezo thin-film elements by means of which the mirror element is operated resonantly in the first direction and in the second direction. The result is what is known as Lissajous scanning. Compared to raster scanning, this enables a higher image resolution with the same resonant frequency for the fast deflection axis, i.e. for the first axis of rotation in the embodiments described above. The following parameters, which result from the required image resolution and repetition frequency, can be specifically set depending on the application:
Diameter of the mirror element
Maximum deflection angle in the respective orthogonal deflection directions. Using the diameter of the mirror as the cut-out results in the diffraction-limited image resolution.
Operating frequency in the respective direction. This results in the image resolution and refresh rate, which can be weighed against each other by fine-tuning the frequency ratio of the two directions.
Flatness of the mirror at every operating point to avoid imaging errors, pixel smearing and speckle patterns.
The mirror element should oscillate harmoniously around both axes of rotation by selecting suitable amplitudes for the alternating current signals so that there is no dependence of the resonant frequency on the amplitude in order to ensure a stable frequency ratio.
The resonances of the mirror element should not have too narrow a bandwidth in order to enable the fine adjustment mentioned above.
Compact design
Shock resistance

In particular, the mirror component described herein may provide a 2D design that can sufficiently fulfill all requirements for a resolution of 1024×768 pixels. The mirror component may particularly preferably have one or more or all of the following features:
Torsional oscillations for both directions to ensure harmonic oscillation even for larger amplitudes
The same thickness for all moving parts to avoid high process costs
The two frequencies are clearly different. This means that the suspension of the mirror element can be optimized for one direction. This also allows the thickness to be reduced slightly.
The desired mirror element diameter, the suspension, the desired frequency and the required flatness in conjunction with the material determine the thickness.
The dimensioning of the first torsion spring elements results from the already defined actual mirror element, from the required frequency and deflection and from the load capacity of the material.
The second torsion spring elements are mounted outside the drive ring and are preferably rotated by 90° to the first torsion spring elements.
The drive for the second torsional oscillation is preferably also on the movable drive ring. This has the advantage of a compact design, and the frequency is also reduced by the moment of inertia of the drive ring.

Furthermore, the piezoelectric mirror component described herein may have one or more of the following advantages:
Both oscillations are realized via torsion spring elements, which means that the oscillation is harmonious even for high deflections. This avoids the anharmonicity caused by bending of the suspension in many other designs, such as the so-called “quad pod” designs.
The second torsion spring elements for the slower oscillation are arranged outside the drive ring. This is also moved. This makes it possible to optimize the drive for the first torsional oscillation without significantly influencing the properties of the second torsional oscillation.
Both oscillations can share one drive ring. This results in a very compact design.
The elliptical symmetry of the drive ring gives you more lines of freedom to adjust the properties, in particular the frequencies and deflection angles, of the two orthogonal torsional oscillations separately. For example, the ellipticity of the drive ring can be optimized in order to obtain the best control of the first torsional oscillation.

In a particularly preferred embodiment, the mirror component has the following properties, with which a resolution of 1024×768 pixels with a full-screen refresh rate of just under 50 Hz can preferably be achieved:
Material: Silicon
Metal of the first electrode: Platinum
Metal of the second electrode: Gold
Metal of the reflective coating: aluminum
Thickness of the silicon: 175 μm
Diameter of the mirror region with the reflective coating: 1.7 mm
Torsion spring elements: 175 μm wide, 1 mm long
Drive ring: 0.7 to 0.95 mm wide.
Material of the piezoelectric layer: PZT with a thickness in the region of 1 to 2 μm.

In a further particularly preferred embodiment, the mirror component has the following properties, with which a resolution of 1024×768 pixels with a full-screen refresh rate of just under 50 Hz can preferably be achieved:
Material: Silicon
Metal of the first electrode: Platinum
Metal of the second electrode: Gold
Metal of the reflective coating: aluminum
Thickness of the silicon: 150 μm
elliptical mirror region with reflective coating
Elliptical axis lengths of the mirror region: 1.6 mm×1.7 mm
Torsion spring elements: 150 μm wide, 0.6 to 0.8 mm long
Drive ring: 0.7 to 1.35 mm wide.
Material of the piezoelectric layer: PZT with a thickness in the region of 1 to 2 μm.

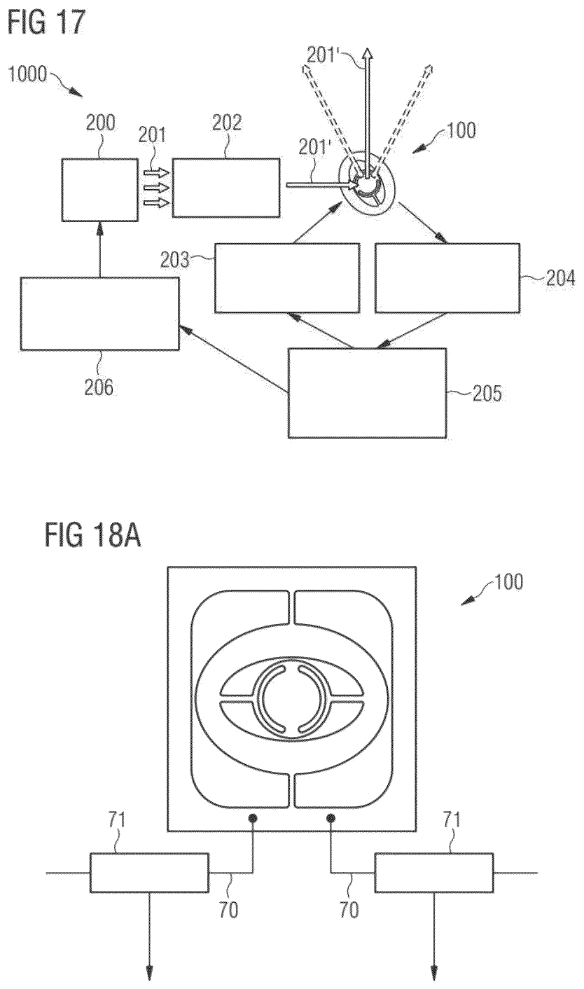

FIG. 17 shows a schematic illustration of a projection device 1000 according to a further embodiment, which has a piezoelectric mirror component 100 according to the previous description. Furthermore, the projection device has a laser light source 200 which emits laser light 201 during operation.

For example, the laser light source 200 can be a so-called RGB light source, which can emit red, green and blue laser light. For this purpose, the laser light source 200 can, for example, have three laser diodes or laser diode groups that can be modulated accordingly. The laser light beams can, for example, be superimposed in a beam combiner 202, so that a beam of combined laser light 201′ can be irradiated onto the piezoelectric mirror component 100 and reflected by it into the desired image region. The laser light source 200 can, for example, be controlled via laser control electronics 206, for example to modulate the amplitude of the laser light over time.

The piezoelectric mirror component 100 can be controlled via mirror component control electronics 203, for example to generate the desired Lissajous figure with which the desired image region can be scanned. Furthermore, sensor electronics 204 may be provided to detect the position and/or frequencies of the mirror element of the mirror component 100, preferably in real time. In addition, image processing electronics 205 may be provided, for example to control the entire image display. This can correspond in particular to the conversion of image or film information into control signals for the laser light source 200 and the mirror component 100, including the temporal synchronization between the mirror element position and the amplitudes of the different lasers.

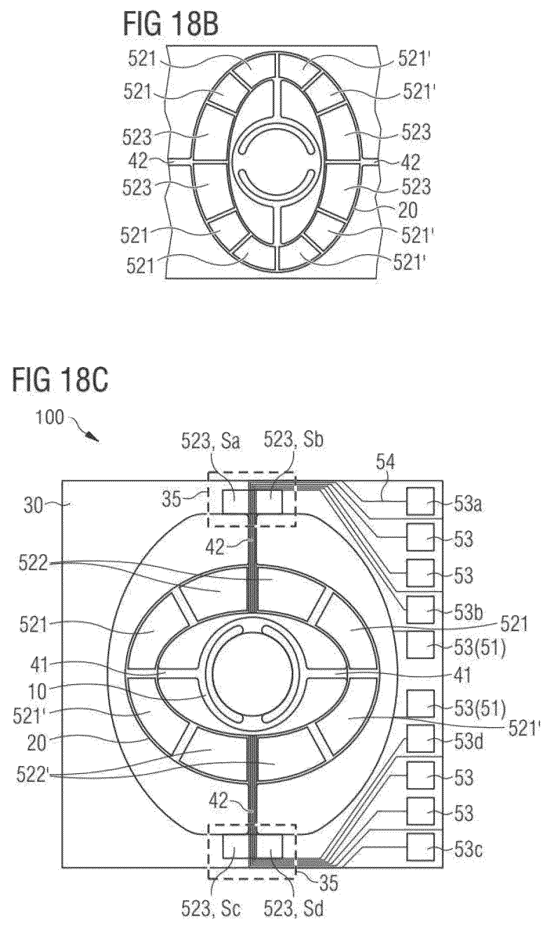

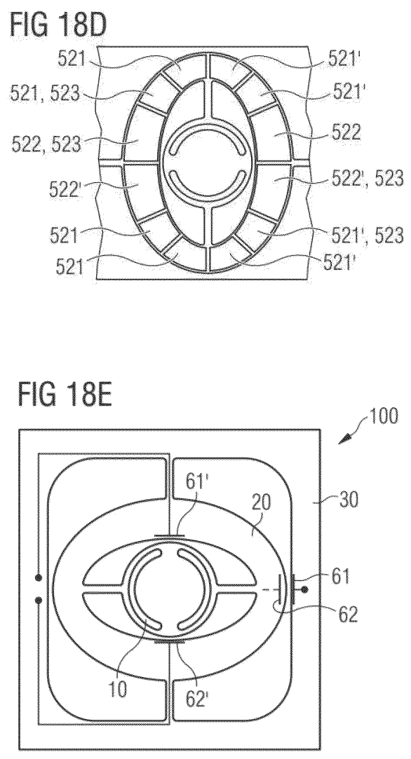

FIGS. 18A to 18E show schematic illustrations of measures for determining the position and/or frequency of components of a piezoelectric mirror component according to some embodiments. These measures may be provided in conjunction with a method for operating the mirror component. For example, such measures may be provided in connection with the previously described sensor electronics 204.

For example, during operation of the piezoelectric mirror component 100, the second frequency can be measured in the first alternating current signal and the first frequency can be measured in the second alternating current signal. As indicated in FIG. 18A, this can be achieved, for example, by using suitable frequency filters 71 in the drive supply lines 70, so that no additional lines are required.

Furthermore, as indicated in FIGS. 18B and 18C, it may also be possible to provide third actuation regions 523 in addition to the first and second actuation regions, in which a piezoelectric signal can be measured via the piezoelectric effect. The third actuation regions 523, which may also be referred to as sensor elements or sensor regions, may in particular be provided at suitable positions so that a good signal can be obtained.

For example, the third actuation regions 523 may be placed on the drive ring 20, for example close to the first or, as shown in FIG. 18B, close to the second torsion spring elements 42. That a third actuation region is arranged “close to a torsion spring element” may in particular mean that said third actuation region is arranged close to or next to a base of the respective torsion spring element and no first and second actuation region is arranged closer to the respective torsion spring element than said third actuation region. In FIG. 18B, purely by way of example, four third actuation regions 523 are provided which are arranged symmetrically with respect to the first and second torsion spring elements 42.

Furthermore, third driving regions 523 can also be formed on the frame element 30, as shown in FIG. 18C. In this way it can be achieved that the drive ring 20 can be completely available for driving actuation regions 521, 521′, 522, 522′. Furthermore, the third actuation regions 523 on the frame element 30 are easier to produce and easier to contact, since no additional conductor tracks 54 have to be routed via the second torsion spring elements 42 for contacting them.

As indicated in FIG. 18C, four third actuation regions 523, for example, can be arranged symmetrically to the first and second torsion spring elements 42 as sensor elements Sa, Sb, Sc, Sd. The sensor elements Sa, Sb, Sc, Sd can be contacted by contact elements 53a, 53b, 53c, 53d and conductor tracks 54.

For example, as shown, two third actuation regions 523 forming the sensor elements Sa and Sb may be arranged at the base of one of the two second torsion spring elements 42 and two further third actuation regions 523 forming the sensor elements Sc and Sd may be arranged at the base of the other of the two second torsion spring elements 42 symmetrically with respect to the axis formed by the second torsion spring elements 42. The frame element 30 may be thinned below the second actuation portions 523 and, in particular, may have the same thickness as the drive ring 20, for example, to allow mechanical movement of the third actuation portions 523. For example, the frame element 30 may have a reduced thickness, for example the same thickness as the drive ring 20, in the dashed marked regions 35 where the third actuation portions 523 are located, while the remainder of the frame element 30 or at least an edge portion of the frame element may have a greater thickness than the regions 35 as described above. In other words, the third actuation regions are preferably arranged in one or more regions of the frame element 30 which have a reduced thickness compared to the rest of the frame element 30 or at least compared to an edge part of the frame element 30.

Due to the described arrangement of sensor elements Sa, Sb, Sc and Sd on the frame element 30, deflections in both directions, i.e. deflections about the first torsion elements 41 and deflections about the second torsion elements 42, can be detected simultaneously. Linear combinations of the signals of the four sensor elements Sa, Sb, Sc, Sd formed by the third actuation regions 523 can be used for this purpose. If the signals of the sensor elements are also labeled Sa, Sb, Sc and Sd for the sake of simplicity, oscillations around the first torsion spring elements 41 can be detected by one or more of the linear combinations |Sa+Sb|, |Sc+Sd|, |Sa−Sc| and |Sb−Sd| of the signals of the sensor elements Sa, Sb, Sc and Sd and deflections around the second torsion spring elements 42 can be detected by one or more of the linear combinations |Sa+Sc|, |Sb+Sd|, |Sa−Sb| and |Sc−Sd| of the signals of the sensor elements Sa, Sb, Sc and Sd. The measurement accuracy can be increased by using several of the aforementioned linear combinations. Alternatively, it may also be possible that, for example, only two third actuation regions 523 are present, since these are in principle sufficient to obtain the desired information. For example, only those third actuation regions 523 may be present which form the sensor elements Sa and Sb or which form the sensor elements Sa and Sc or which form the sensor elements Sc and Sd or which form the sensor elements Sb and Sd. In other words, in the case of only two sensor elements, the two sensor elements should not be arranged diagonally to each other, but should be arranged on a same side with respect to the first torsion spring elements 41 or the second torsion spring elements 42.

In addition, it may also be possible for first and/or second actuation regions to be present which are used alternately in a time-division multiplexing process to drive the mirror element or the drive ring and to measure a piezoelectric signal. For this purpose, as indicated in FIG. 18C, at least some first or second actuation regions 521, 521′, 522, 522′ may be present, for example, which are simultaneously provided as third actuation regions. In particular, this can mean that the drive and the position determination are carried out at different times. This can be achieved, for example, by suitable pulse width modulation, wherein the mirror element is driven alternately for a certain number of periods and the measurement is carried out for a smaller number of periods. Due to the high mechanical quality, only little deflection of the mirror element is lost.

Furthermore, for position and/or frequency measurement, as indicated in FIG. 18D, at least two electrode elements 61, 61′, 62, 62′ can be present which form a capacitor which has a variable capacitance when the mirror element 10 or the drive ring 20 is moved, the capacitance of the capacitor being measured. The electrode elements 61, 61′, 62, 62′ can, for example, be formed by conductor track parts. A first electrode element 61 can, for example, be arranged on the frame element 30, while a second electrode element 62 is arranged on the drive ring 20 adjacent to the first electrode element 61. When the drive ring 20 is moved relative to the frame element 30, the distance between the electrode elements 61, 62 can change, as a result of which the capacitance of the capacitor formed by the electrode elements 61, 62 can change. Accordingly, electrode elements can also be arranged on the drive ring 20 and the mirror element 10, for example.

It may also be possible, for example, to arrange two electrode elements 61′, 62′ on opposite sides of the drive ring 20 on the frame element 30. The drive ring 20 can then act like a moving dielectric between the electrode elements 61′, 62′ during a movement. Accordingly, two electrode elements can also be arranged on the drive ring 20 on opposite sides of the mirror element 10.

In particular, the zero crossing of the drive ring 20 and/or the mirror element 10 can also be determined during such capacitive measurements. In order to avoid a capacitive short circuit, the first electrode can be suitably patterned.

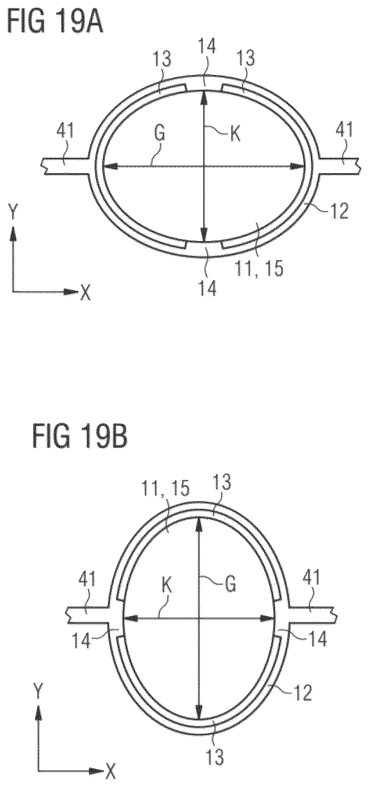

In conjunction with the figures described above, a circular mirror region 11 is shown throughout. Alternatively, the mirror region 11 and thus also the reflective coating 15 can also be elliptical, as shown in FIGS. 19A and 19B in sections of mirror components, and have a larger elliptical axis G and smaller elliptical axis K. Preferably, the larger ellipse axis G is oriented along the first direction and the smaller ellipse axis K is oriented along the second direction, as shown in FIG. 19A. Alternatively, the larger elliptical axis G can be oriented along the second direction and the smaller elliptical axis K along the first direction, as shown in FIG. 19B. In the case of an elliptical mirror region 11, the cut-outs 13 have the shape of elliptical arcs. The ratio of the larger elliptical axis G to the smaller elliptical axis K can, for example, be greater than 1 or greater than or equal to 1.02 or greater than or equal to 1.04 or greater than or equal to 1.06 as well as less than or equal to 1.1 or less than or equal to 1.08 or less than or equal to 1.07.

The features and embodiments described in connection with the figures can be combined with one another in accordance with further embodiments, even if not all combinations are explicitly described. Furthermore, the embodiments described in connection with the figures may alternatively or additionally have further features as described in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1. A piezoelectric mirror component, comprising:
a mirror element,
a piezoelectric drive ring which surrounds the mirror element and is connected to the mirror element via at least a first torsion spring element, and
a frame element, which is connected to the drive ring via at least one second torsion spring element.

2. The piezoelectric mirror component according to claim 1, wherein the drive ring has an elliptical shape.

3. The piezoelectric mirror component according to claim 1, wherein the at least one first torsion spring element is arranged along the first direction and the at least one second torsion spring element is arranged along the second direction.

4. The piezoelectric mirror component according to claim 1, wherein the drive ring is connected to the mirror element via two first torsion spring elements arranged along a straight line on two opposite sides of the mirror element, and the drive ring is connected to the frame element via two second torsion spring elements arranged along a straight line on two opposite sides of the drive ring.

5. The piezoelectric mirror component according to claim 1, wherein
the mirror element has a mirror region and an edge region surrounding the mirror region, which is partially separated from the mirror region by means of two cut-outs, and
the edge region is connected to the mirror region via two connection regions.

6. The piezoelectric mirror component according to claim 5, wherein a reflective coating is applied to the mirror region, and the edge region and the connection regions are free of the reflective coating.

7. The piezoelectric mirror component according to claim 5, wherein the mirror region is circular or elliptical.

8. The piezoelectric mirror component according to claim 1, wherein the frame element surrounds the drive ring and has a recess penetrating the frame element, in which recess the drive ring and the at least one second torsion spring element are arranged.

9. The piezoelectric mirror component according to claim 1, wherein the mirror element and the drive ring have a smaller thickness than at least one edge part of the frame element and the frame element, the drive ring, the mirror element and the torsion spring elements are formed in one piece.

10. The piezoelectric mirror component according to claim 1, wherein a first electrode and a second electrode patterned into a plurality of actuation regions are applied to the drive ring and a piezoelectric layer is arranged between the first and second electrodes.

11. The piezoelectric mirror component according to claim 10, wherein the first electrode and at least partially the piezoelectric layer are applied to the frame element.

12. The piezoelectric mirror component according to claim 11, wherein the second electrode is applied in an actuation region of the frame element surrounded by an edge part and the actuation region has a smaller thickness than the edge part.

13. The piezoelectric mirror component according to claim 12, wherein the actuation region is partially separated from the edge part by means of at least one cut-out.

14. The piezoelectric mirror component according to claim 10, wherein
there are contact elements on the frame element for controlling the first and second electrodes, and
actuation regions of the second electrode are connected to contact elements via conductor tracks that run over the at least one second torsion spring element.

15. The piezoelectric mirror component according to claim 1, wherein at least two electrode elements are present which form a capacitor having a variable capacitance upon movement of the mirror element or the drive ring.

16. The piezoelectric mirror component according to claim 1, wherein at least two third actuation regions are arranged on the frame element on a same side with respect to the at least one first torsion spring element or the at least one second torsion spring element.

17. The piezoelectric mirror component according to claim 16, wherein the third driving regions are arranged in one or more regions of the frame element which have a smaller thickness compared to at least one edge portion of the frame element.

18. A method for operating a piezoelectric mirror component according to claim 1, wherein the mirror element is set into a first torsional oscillation by means of a first electrical alternating current signal having a first frequency acting on first actuation regions and the drive ring is set into a second torsional oscillation by means of a second electrical alternating current signal having a second frequency acting on second actuation regions.

19. The method according to claim 18, wherein the second frequency is measured in the first alternating current signal and the first frequency is measured in the second alternating current signal during operation of the piezoelectric mirror component.

20. The method according to claim 18, wherein third actuation regions are present in which a piezoelectric signal is measured.

21. The method according to claim 18, wherein the capacitance of the capacitor is measured.

22. The method according to claim 18, wherein first and/or second actuation regions are provided which are alternately used in a time-division multiplexing method for driving the mirror element or the drive ring and for measuring a piezoelectric signal.

23. A projection device, comprising:
a laser light source and
a piezoelectric mirror component according to claim 1.

24. The piezoelectric mirror component according to claim 1, wherein the drive ring has a first diameter along a first direction and a second diameter along a second direction perpendicular to the first direction and the first diameter is greater than the second diameter.

25. The piezoelectric mirror component according to claim 1, wherein measures are provided for achieving a position determination of the mirror element and/or a position determination of the drive ring and/or a frequency determination of one or both torsional oscillations.
